(19) United States
(12) Patent Application Publication
(10) Pub. No.: US 2012/0086084 A1
(43) Pub. Date: Apr. 12, 2012

(54) SEMICONDUCTOR DEVICE

(75) Inventor: Masanori KIKUCHI, Chuo-ku (JP)

(73) Assignee: ELPIDA MEMORY, INC., Tokyo (JP)

(21) Appl. No.: 13/267,612

(22) Filed: Oct. 6, 2011

(30) Foreign Application Priority Data
Oct. 7, 2010 (JP) 2010-227729
Aug. 30, 2011 (JP) 2011-187229

(51) Int. Cl. H01L 27/092

(52) U.S. Cl. 257/369; 257/E27.062

(57) ABSTRACT

A semiconductor device comprise a memory cell region and a peripheral circuit region on a semiconductor substrate, and a metal laminating wiring extending over the memory cell region and the peripheral circuit region. The metal laminating wiring is a bit line in the memory cell region, and is a portion of a wiring for the peripheral circuit region connected to the bit line and a portion of a gate electrode connected to the wiring for the peripheral circuit region, in the peripheral circuit region. A height of a bottom surface of the metal laminating wiring disposed in the memory cell region, from an upper surface of the semiconductor substrate is substantially the same as the height of the bottom surface of the metal laminating wiring disposed in the peripheral circuit region, from the upper surface of the semiconductor substrate.

This application is based upon and claims the benefit of priority from Japanese Patent Application No. 2011-187229 filed on Aug. 30, 2011, and Japanese Patent Application No. 2010-227729 filed on Oct. 7, 2010, the disclosure of which is incorporated herein in its entirety by reference.

### TECHNICAL FIELD

The present invention relates to a semiconductor device.

### RELATED ART

Recently, in order to improve an operation speed of a semiconductor device, particularly, DRAM (Dynamic Random access Memory) device, a poly metal gate structure is adapted. A poly metal gate structure is a gate electrode structure where metal film is laminated on a polysilicon film, and can reduce the plane resistance (sheet resistance) of a word line as compared with a polycide gate structure which has been conventionally used.

Also, JP11-233451 A1 discloses that a film of metal nitride such as tungsten nitride (WN) is formed between a polysilicon film and a metal film, to inhibit reaction between the polysilicon film and a metal film.

JP2003-163348 A1 discloses that a thin silicide film between a polysilicon film and a metal film is formed, to inhibit reaction between the polysilicon film and metal film.

A dual gate structure is also adapted in order to improve performance and reduce a operation voltage of devices. A dual gate structure uses a gate electrode comprising an n-type silicon film, into which n-type impurity such as phosphorous is implanted, as a gate electrode of an n-channel MOS transistor, and a gate electrode comprising a p-type silicon film, into which p-type impurity such as boron is implanted, as a gate electrode of an p-channel MOS transistor.

With reference to FIGS. 1 and 2, a dual gate structure will be explained below. A poly-metal gate electrode made of a laminate of a polysilicon film, a silicide film, and a metal nitride film are applied to the dual gate structure.

As shown in FIG. 1A, isolation region 42 is formed in a predetermined region of a semiconductor substrate 41 by STI (Shallow Trench Isolation). In a predetermined region of the semiconductor substrate 41, boron (B) as p-type impurity is doped into the semiconductor substrate 41 to form a P-well 46, and phosphorous (P) as n-type impurity is doped into the semiconductor substrate 41 to form an N-well 47. Subsequently, the surface of the semiconductor substrate 41 is thermally oxidized to form a gate insulating film 43 having a thickness of about 4 nm. On the gate insulating film 43, a non-doped polysilicon film 44 is formed so as to have a thickness of about 100 nm by CVD (Chemical Vapor Deposition). The polysilicon film on the N-well 47 is covered with a resister mask 45a, and phosphorus (P) is ion-injected into the polysilicon film on the P-well 46 as n-type impurity, to form an N-type polysilicon film 44a.

As shown in FIG. 1B, after removing the resistor mask 45a, the polysilicon film 44 on the P-well 46 is covered with a resister mask 45b, and boron (B) is ion-injected into the polysilicon film on the N-well 47 as p-type impurity, to form a P-type polysilicon film 44b. A natural oxide film (not shown) formed on the surface of the polysilicon film 44 (N-type polysilicon film 44a and P-type polysilicon film 44b) is removed.

As shown in FIG. 2, a tungsten silicide (WSi₂) film 50 is formed as a silicide film on the polysilicon film 44. The WSi₂ film 50 is continuously formed on the N-type polysilicon film and P-type polysilicon film. Thereafter, a tungsten nitride (WN) film and a tungsten (W) film are laminated in this order on the WSi₂ film 50, and then, a poly-metal structure gate electrode is formed by patterning.

JP2006-310842 A1 discloses a poly-metal structure advantageous to resistance reduction of a DRAM word line. The poly-metal structure comprises a polysilicon film, a barrier film, and a tungsten film as a fundamental structure, and the tungsten nitride (WN) in the barrier film is replaced with titanium nitride (TiN), thereby improving the heat resistance of the barrier film. JP2006-310842 A1 also discloses that it is valid to form metal silicide such as Ti-silicide, between a polysilicon film and a barrier film, and to form W silicide as a baffer film between a barrier film and a W film.

### SUMMARY OF THE INVENTION

In one embodiment, there is provided a semiconductor device, comprising:

a memory cell region and a peripheral circuit region on a semiconductor substrate; and

a metal laminating wiring extending over the memory cell region and the peripheral circuit region,

wherein the metal laminating wiring is a bit line in the memory cell region,

the metal laminating wiring is a portion of a wiring for the peripheral circuit region connected to the bit line and a portion of a gate electrode connected to the wiring for the peripheral circuit region, in the peripheral circuit region, and

a height of a bottom surface of the metal laminating wiring disposed in the memory cell region, from an upper surface of the semiconductor substrate is substantially the same as the height of the bottom surface of the metal laminating wiring disposed in the peripheral circuit region, from the upper surface of the semiconductor substrate.

In another embodiment, there is provided a semiconductor device,

comprising:

a memory cell region and a peripheral circuit region on a semiconductor substrate;

a metal laminating wiring extending over the memory cell region and the peripheral circuit region;

a buried gate electrode, and first and second impurity diffusion layers formed in the semiconductor substrate in opposite sides of the buried gate electrode, in the peripheral circuit region;

an n-channel MOS transistor including a gate electrode, and a p-channel MOS transistor including a gate electrode, in the memory cell region,

wherein the metal laminating wiring is a bit line connected to the first impurity diffusion layer through a bit line contact plug in the memory cell region,

the metal laminating wiring is a portion of a wiring for the peripheral circuit region connected to the bit line and portions of the gate electrodes of the n-channel MOS transistor and the p-channel MOS transistor connected to the wiring for the peripheral circuit region, in the peripheral circuit region, and

a height of a bottom surface of the metal laminating wiring disposed in the memory cell region, from an upper surface of the semiconductor substrate is substantially the same as the height of the bottom surface of the metal laminating wiring disposed in the peripheral circuit region, from the upper surface of the semiconductor substrate.

### BRIEF DESCRIPTION OF THE DRAWINGS

The above features and advantages of the present invention will be more apparent from the following description of certain preferred embodiments taken in conjunction with the accompanying drawings, in which:

FIGS. 1 and 2 show a related method for manufacturing the semiconductor device.

FIG. 3 is plane view of a semiconductor device according to the first exemplary embodiment.

FIG. 4 is cross sectional view of a semiconductor device according to the first exemplary embodiment.

FIGS. 5 to 23 show a method for manufacturing for a semiconductor device according to the first exemplary embodiment.

FIGS. 24 to 26 show a method for manufacturing for a semiconductor device according to the second exemplary embodiment.

FIG. 27 is a cross sectional view of a semiconductor device according to the third exemplary embodiment.

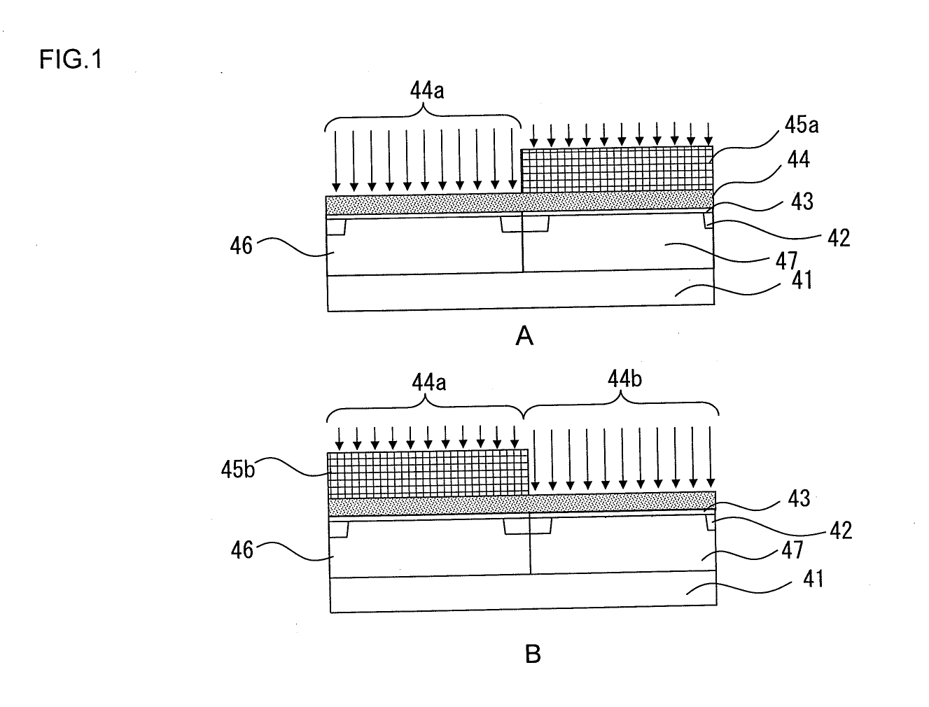

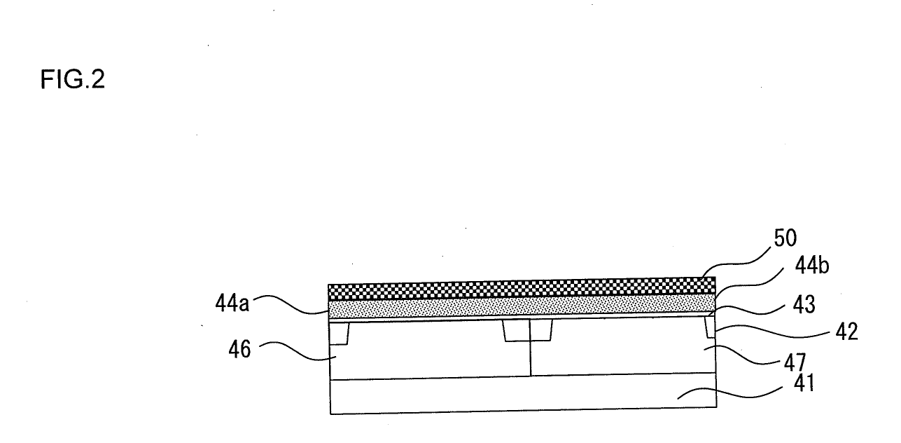

In the drawings, reference numerals have the following meanings: 1; semiconductor substrate, 2, 5, 8, 8a; mask, 3, 6, 21; trench, 4, 7; isolation region, 8b; protection film, 9; n-type diffusion layer, 9a; capacitor diffusion layer, 9b; bit line diffusion layer, 10; mask insulating film, 11, 11a; gate trench, 12; trench diffusion layer, 13, 17; gate insulating film, 14; buried gate electrode, 14a; titanium (TiN) nitride film, 14b; tungsten (W) film, 15; cap insulating film, 16, 20, 29; mask, 18; amorphous silicon film, 18a; n-type impurity containing silicon film, 18b; p-type impurity containing silicon film, 19; silicon oxide film, 21, 21b; opening, 22; amorphous silicon film, 22a; bit line contact plug, 23; titanium silicide (TiSi) film or titanium (Ti) film, 24; titanium nitride (TiN) film, 25; tungsten silicide (WSi) film, 26; tungsten (W) film, 27; metal laminating film, 28; cover insulating film, 30; bit line, 30a; n-type gate electrode, 30b; p-type gate electrode, 31a, 31b; sidewall insulating film, 32a; n-type impurity containing source/drain diffusion layers, 32b; p-type impurity containing source/drain diffusion layers, 33; first interlayer insulating film, 34; capacitor contact plug, 34a; source/drain contact plug, 35; lower electrode, 35a; wiring, 36; upper electrode, 37; second interlayer insulating film, 37a; third interlayer insulating film, 38, 38a; contact plug, 39, 39a; upper wiring, 41; semiconductor substrate, 42; isolation region, 43; gate insulating film, 44; impurity containing polysilicon film, 44a; N-type polysilicon film, 44b; P-type polysilicon film, 45a, 45b; resistor mask, 46; P-well, 47; N-well, 48 titanium silicide (TiSi) film, 49; titanium nitride (TiN) film, 50; tungsten silicide, 50a; silicide film of a first metal, 51; a first metal film, 52; sidewall, 56; source and drain diffusion layers, 100; sense amplifier, 200; sub-word driver, AR1, AR2; active region, Tr1, Tr2; cell transistor

### DETAILED DESCRIPTION OF THE REFERRED EMBODIMENTS

The invention will be now described herein with reference to illustrative embodiments. Those skilled in the art will recognize that many alternative embodiments can be accomplished using the teachings of the present invention and that the invention is not limited to the embodiments illustrated for explanatory purposes.

### First Exemplary Embodiment

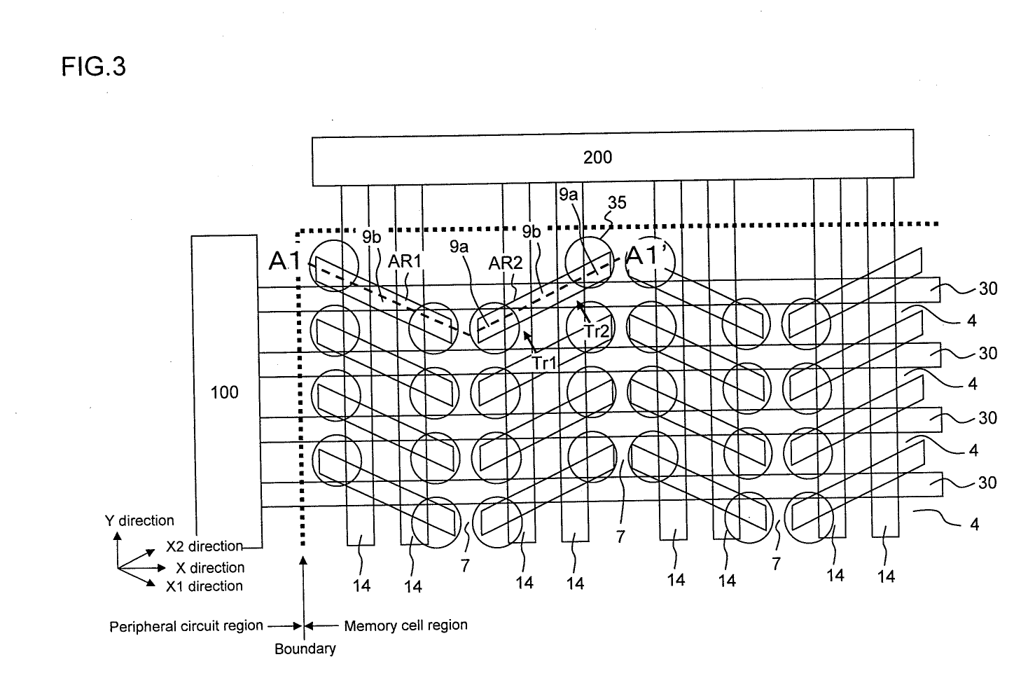

A DRAM (Dynamic Random Access Memory) semiconductor device, to which a gate electrode is applicable, will be explained below, with reference FIGS. 3 to 23.

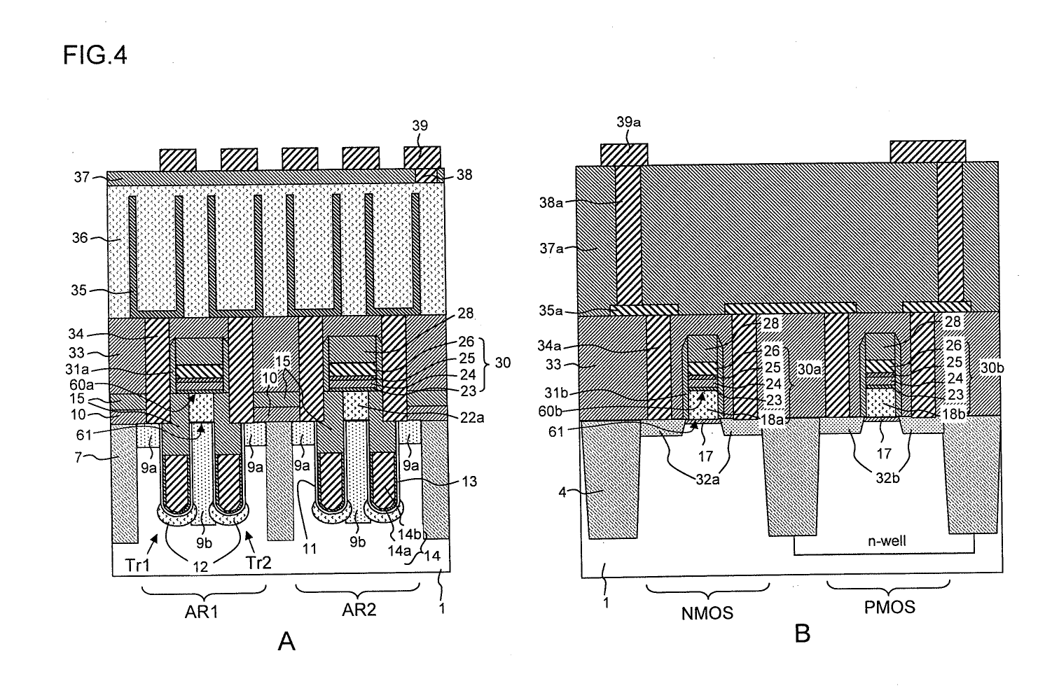

First, a semiconductor device will be explained, with reference to FIGS. 3 and 4. FIG. 3 is a plane view of a memory cell region of a DRAM, and FIG. 4A is a cross-sectional view of the A1-A1′ direction in FIG. 3. FIG. 4B is a cross-sectional view of a peripheral circuit region.

The plane view of FIG. 3 shows a plurality of bit lines 30 that extend to the X direction and is connected to a sense amplifier 100 of a peripheral circuit region disposed in one end of a memory cell region. FIG. 3 also shows a plurality of buried gate electrodes 14 that are word lines extending to the Y direction vertically crossing the X-direction. The buried gate electrodes 14 contact a sub-word driver 200 of a peripheral circuit region disposed in one end of a memory cell region. There is a boundary illustrated by a dotted line between the memory cell region and peripheral circuit region including the sense amplifier 100 and sub-word driver 200. The memory cell region is isolated by isolation region 7 in the X direction and comprises a plurality of active regions AR1 and AR2 isolated by isolation region 4 in the Y direction. The active regions AR1 extend to the X1 direction that is inclined 30° downward to right in the X direction and is disposed at the same pitch in the Y direction. The active regions AR2 extend to the X2 direction that is inclined 30° upward to right in the X direction and is disposed at the same pitch in the Y direction. The active regions AR1 and AR2 are alternatively disposed at the same pitch in the X direction. In each active region AR, two buried gate electrodes 14 extending to the Y direction are disposed so that they extend across each active region AR.

In an active region disposed between two buried gate electrode 14, a bit line diffusion layer (portion of first impurity diffusion layer) 9b connected to a bit line 30 is formed. Also, in each of the two portions of active region that are disposed in both ends of an active region AR and between the buried gate electrode 14 and an isolation region 7, a capacitor diffusion layer 9a (second impurity diffusion layer) connected to a lower electrode 35 of a capacitor is formed. The buried gate electrode 14 extending to the Y direction is formed over a plurality of active regions AR disposed in the Y direction and a plurality of isolation regions 4 disposed between a plurality of active regions AR. Also, each of a plurality of bit lines 30 extending to the X direction is formed on a straight line connecting bit line diffusion lines 9b of a plurality of active regions AR disposed in the X direction.

Two cell transistors Tr1 and Tr2 are formed in each active region AR. Both of the cell transistors are buried gate-type recess channel MOS transistors. The transistor Tr1 comprises a buried gate electrode 14, and a capacitor diffusion layer 9a (second impurity diffusion layer) and a bit line diffusion layer 9b (portion of first impurity diffusion layer) in opposite sides of the buried gate electrode 14. For convenience, the capacitor diffusion layer 9a is a drain diffusion layer and the bit line diffusion layer 9b is a source diffusion layer. If a bias application state is reversed, the source diffusion layer and drain diffusion layer are reversed. The transistor Tr2 comprises a buried gate electrode 14, and a bit line diffusion layer 9b and a capacitor diffusion layer 9a in opposite sides of the buried gate electrode 14. The bit line diffusion layer 9b is shared in two cell transistors.

In the cross-sectional view of FIG. 4A, active regions AR1 and AR2 are isolated by an isolation region 7 formed on the surface of a p-type single crystal silicon substrate 1 (hereinafter, referred to as a “substrate”). In each active region AR, two gate trenches 11 are formed. A gate insulating film 13 is formed in the inner surface of each gate trench 11. Also, a buried gate electrode 14 is formed in contact with the gate insulating film 13 so that the bottom portion of the gate trench 11 is buried with it. The buried gate electrode 14 as a word line is a laminate film of titanium nitride (TiN) 14a and tungsten (W) 16b. A cap insulating film 15 comprising a silicon nitride film is formed to be adjacent to the upper surface of the buried gate electrode 14.

On each surface of the substrate 1 between each gate trench 11 and the isolation region 7, a capacitor diffusion layer 9a as a drain diffusion layer is formed. The bottom surface of the capacitor diffusion layer 9a is deposited at lower position than the upper surface of the buried gate electrode 14, but may be adjacent to a position identical to the upper surface of the buried gate electrode 14. But, it is not preferable to locate the bottom surface of the capacitor diffusion layer 9a at deeper position than the upper surface of the buried gate electrode 14, because leakage current of the gate insulating film increases.

On the surface of the substrate 1 sandwiched between the gate trenches 11, a bit line diffusion layer 9b as a source diffusion layer is formed. The bottom surface of the bit line diffusion layer 9b is located deeper than the deepest portion of the gate trench 11. Also, a trench diffusion layer 12 is formed on the surface of the substrate 1 adjacent to the bottom surface of each gate trench 11. Trench diffusion layer 12 in one active region AR is connected to the bit line diffusion layer 9b that is formed deeper than the deepest portion of the gate trench 11. Therefore, the source diffusion layer (first impurity diffusion region) comprises the bit line diffusion layer 9b and the trench diffusion layer 12 connected to the bit line diffusion layer 9b.

For example, a transistor Tr1 comprises a gate insulating film 13 formed on the inner surface of a gate trench 11, a buried gate electrode 14 covering the gate insulating film 13, a capacitor diffusion layer 9a as drain diffusion layer, a bit line diffusion layer 9b as source diffusion layer, and a trench diffusion layer 12. The channel region of the transistor Tr1 is a sidewall of the gate trench 11 sandwiched between the bottom surface of the capacitor diffusion layer 9a and the upper portion of the trench diffusion layer 12, and is the surface of a substrate 1 contacting with the gate insulating film 13. In such structure, since a substrate region between adjacent buried gate electrodes 14 is not a channel region and is substituted by the bit line diffusion layer 9b containing high concentration impurity, and the trench diffusion layer 12 is formed in the bottom of the gate trench 11, the channel region of each transistor is formed only in each far sidewall of each gate trench 11. As a result, when one of two memory cells in one active region storages “1” information and the buried gate electrode in the other of the two memory cells is repetitively on or off, it is possible to avoid disturb defects that change “1” storage state of one of two memory cells to “0” state.

On the upper surface of an isolation region 7 and the upper surface of a substrate 1 wherein a capacitor diffusion layer 9a is formed, a mask insulating film 10 comprising a silicon oxide film, which is used as a mask when forming a gate trench 11, is provided. Also, a cap insulating film 15 covering the mask insulating 10 and burying the gate trench 11 on a buried gate electrode 14 is provided. The upper surface of the cap insulating film 15 is located upward from the upper surface of the substrate 1 by the sum of the thickness of the mask insulating film 10 and the thickness of cap insulating film 15 (the thickness of the cap insulating film 15 on the mask insulating film 10). On the upper surface of the bit line diffusion layer 9b which is disposed between adjacent cap insulating films 15 formed to be protruded upward from the upper surface of the substrate 1, a bit line contact plug 22a comprising a silicon film contacting with the bit line diffusion layer 9b is formed. The upper surface of the bit line contact plug 22a is flush with the upper surface of the cap insulating film 15.

On the upper surface of the bit line contact plug 22a, a bit line 30 made of a metal laminating film is formed. The bit line 30 comprises a metal laminating film including a metal buffer film 23 contacting with the upper surface of the bit line contact plug 22a or the cap insulating film 15, a TiN film 24 adjacent onto the metal buffer film 23, a tungsten silicide film 25 (hereinafter referred to as a “WSi film;” corresponding to a silicide film of a first metal) adjacent onto the TiN film 24, and a W film 26 (first metal film) adjacent onto the WSi film 25. When titanium (Ti) is used as metal for the metal buffer film 23, a portion of the metal buffer film 23 contacting with the upper surface of the bit line contact plug 22a made of silicon film is made of a silicide (hereinafter described as “TiSi”) film, and a portion of the metal buffer film 23 contacting with the upper surface of the cap insulating film 15 is made of a Ti film. On the W film 26, a cover insulating film 28 comprising a silicon nitride film is formed. In a sidewall of a bit line 30 comprising the cover insulating film 28, a sidewall insulating film 31a comprising a silicon nitride film is formed. The bit line 30 is a poly-metal wiring structure when seeing it at the bit line contact plug 22a in a longitudinal direction, but is a metal wiring structure not including a silicon film on the cap insulating film 15, in which a bit line contact plug 22a is not present. Therefore, it is possible to reduce the height of a wiring by a thickness of a silicon film in the bit wiring extending to the X direction, thereby reducing parasitic capacitance of the bit wiring. Accordingly, it is possible to improve the reliability of DRAM operation even when the capacitor capacity decreases.

A first interlayer insulating film 33 is formed so as to cover a cover insulating film 28. In the first interlayer insulating film 33, a plurality of capacitor contact plugs 34 connected to capacitor diffusion layers 9a are formed. A lower electrode 35 of a capacitor contacting with the upper surface of the capacitor contact plug 34 is formed. The lower electrode 35 has a crown structure, but may have a column shape. Also, a support film is formed to prevent the lower electrode 35 from being broken or twisted, but is not shown in the drawings. In order to cover the lower electrode 35, a capacity insulating film (not shown in the drawings) is formed on the entire surface. Also, an upper electrode 36 covering the capacity insulating film is formed. On the upper electrode 36, a second interlayer insulating film 37 is formed and a contact plug 38 is formed. An upper wiring 39 is formed so as to be connected to the contact plug 38.

With reference to the cross-section view of FIG. 4B, an NMOS region in which an n-channel MOS transistor is formed, and a PMOS region in which a p-channel MOS transistor is formed, are formed. The NMOS region and the PMOS region are isolated by an isolation region 4 in a substrate 1. As the substrate is p-type, an n-well is formed in the PMOS region. On the surface of the substrate 1 in each region, a gate insulating film 17 is formed. On the gate insulating film 17 in the NMOS region, a gate electrode 30a made of a metal laminating film is formed. The metal laminating film comprises an n-type impurity containing polysilicon film 18a, a metal buffer film 23 adjacent onto the upper surface of the polysilicon film 18a, a TiN film 24 adjacent onto the metal buffer film 23, a WSi film 25 adjacent onto the TiN film 24, and a W film 26 adjacent onto the WSi film 25. Also, on the gate insulating film 17 in the PMOS region, a gate electrode 30b made of a metal laminating film is formed. The metal laminating film comprises a p-type impurity containing polysilicon film 18b, a metal buffer film 23 adjacent onto the upper surface of the polysilicon film 18b, a TiN film 24 adjacent onto the metal buffer film 23, a WSi film 25 adjacent onto the TiN film 24, and a W film 26 adjacent onto the WSi film 25. Since in the peripheral circuit region, a whole extent of the metal laminating film 30 is formed on the polysilicon film 18b, the overall metal buffer film 23 contacting with the polysilicon film 18b is made of the TiSi film. On the W film 26, a cover insulating film 28 comprising a silicon nitride film is formed. In sidewalls of the gate electrodes 30a, 30b comprising the cover insulating film 28, a sidewall insulating film 31b comprising a silicon nitride film is formed. On the surface of the substrate 1 in the NMOS region, an n-type impurity containing source/drain diffusion layers 32a are formed, so that a planar-type n-channel MOS transistor is provided. Also, on the surface of the substrate 1 in the PMOS region, a p-type impurity containing source/drain diffusion layers 32b are formed, so that a planar-type p-channel MOS transistor is provided.

A first interlayer insulating film 33 is formed so as to cover a cover insulating film 28. In the first interlayer insulating film 33, contact plugs 34a are formed so as to being connected to each of the source/drain diffusion layers 32a, 32b, and a wiring 35a is formed so as to being connected to the contact plug 34a. A third interlayer insulating film 37a is formed so as to cover the wiring 35a. In the third interlayer insulating film 37a, a contact plug 38a is formed. An upper wiring 39a is formed so as to being connected to the contact plug 38a.

In the memory cell region shown in FIG. 4A, a bit line 30 is a poly-metal wiring structure when seeing it at the bit line contact plug 22a, but is a metal wiring structure not including a silicon film on the cap insulating film 15, in which a bit line contact plug 22a is not present. Therefore, it is possible to reduce the height of a wiring by a thickness of a silicon film in the bit wiring extending to the X direction, thereby reducing the parasitic capacitance of the bit wiring. Accordingly, it is possible to improve the reliability of DRAM operation even when the capacitor capacity decreases. More specifically, since a silicon film connecting a bit line 30 to a bit line diffusion layer 9b is formed as a bit line contact plug 22a, which is sandwiched by a cap insulating film 15, the bit wiring 30 extending to the X direction is made of only a metal conductor including a W film 26, a WSi film 25, a TiN film 24, and a Ti film 23 in portions other than portions connected to the bit line contact plug 22a, and does not comprise a polysilicon film. Therefore, it is possible to decrease the height of the bit line 30, thereby reducing the parasitic capacitance of the bit wiring 30. The detection sensitivity of accumulation charge in a DRAM is constrained by balance between the capacity of a capacitor and the parasitic capacitance of a bit line. When the parasitic capacitance of a bit line increases, it is difficult to operate a DRAM, if the capacity of a capacitor does not increase accordingly. Since this embodiment can reduce the parasitic capacitance of a bit line, it can provide a DRAM operable even when it is miniaturized and thus has a smaller capacitor capacity.

Also, in the memory cell region shown in FIG. 4A and the peripheral circuit region shown in 4B, the thickness of silicon films 18a, 18b included in gate electrodes 30a, 30b formed in the peripheral circuit region is substantially the same as the thickness of a silicon film (length between a bottom surface and top surface of the bit line contact plug 22a) included in a bit line contact plug 22a formed in the memory cell region. In other words, when there is a difference between the thickness of the silicon films 18a, 18b in the peripheral circuit region and the sum the thickness of a mask insulting film 10 and a cap insulating film 15 in the memory cell region, the difference (length) is within the predetermined range. The description, “the difference (length) is within the predetermined range” means that the difference between the position of the upper surface of the silicon film 18a, 18b and the position of the upper surface of the cap insulating film 15 is within ±5 nm in a vertical direction. That is to say, the difference between the position of the bottom surface of the metal laminating wiring in the memory cell region and the position of the bottom surface of the metal laminating wiring in the periphery circuit region is equal or more than −5 nm, and is equal or less than 5 nm. If there is the difference at a boundary between the memory cell region and peripheral circuit region, a step is present at the boundary. In this case, one of the silicon film 18a, 18b and cap insulating film 15 protrudes upward with respect to the other of the silicon film 18a, 18b and cap insulating film 15, thereby generating a step. Whichever film between the silicon film 18a, 18b and cap insulating film 15 protrudes, the acceptable maximum height of the step is 5 nm or less in a vertical direction. The metal laminating wiring extends over the memory cell region and peripheral circuit region, and is the bit line in the memory cell region while it is a portion of the wiring for the peripheral circuit region connected to the bit line and a portion of the gate electrode connected to the wiring for the peripheral circuit region. If the height of the step in the vertical direction is over 5 nm, the odds of disconnecting the metal laminating wiring increase.

As described above, both a metal laminating wiring including from a metal buffer film 23 to a W film 26 in the peripheral circuit region, and a metal laminating wiring including from a metal buffer film 23 to a W film 26 in the memory cell region are formed on the substantially same height from the surface of a substrate 1. In other words, if there is the difference between (a) the height of the bottom surface 60a of a metal laminating wiring (bit line) disposed in the memory cell region, from the upper surface 61 of the substrate, and (b) the height of the bottom surfaces 60b of metal laminating wirings (portions of gate electrodes 30a, 30b and a portion of a wiring 30c for the peripheral circuit region) disposed in the peripheral circuit region, from the upper surface 61 of the substrate, the difference is within the predetermined range (−5 nm ≦the difference ≦5 nm).

If a metal laminating wiring extends over the memory cell region and the peripheral circuit region, continuously and there is a step between the memory cell region and the peripheral circuit region, it is possible to avoid disconnection of a metal laminating wiring at step having a different height. Furthermore, since there is no step height or step having a small different height, it is possible to improve the accuracy of lithography or etching, thereby obtaining more miniaturized bit line and gate electrode.

Also, since a gate electrode in the peripheral circuit region comprises a metal laminating film, which comprises a polysilicon film 18, a metal buffer film 23 made of TiSi film adjacent onto the upper surface of the polysilicon film 18, a TiN film 24 adjacent onto the metal buffer film 23, a WSi film 25 adjacent onto the TiN film 24, and a W film 26 adjacent onto the WSi film 25, it is possible to prevent the impurity in the polysilicon film from diffusing outside the polysilicon film, thereby preventing the gate electrode from being depleted. It is possible to prevent the threshold voltage of an MOS transistor from increasing up to higher value than a measurement value and unevenness of the threshold voltage from increasing. As a result, it is possible to resolve unbalanced operation between an n-type channel MOS transistor and a p-channel MOS transistor included in a sensor amplifier, thereby reducing operation delay.

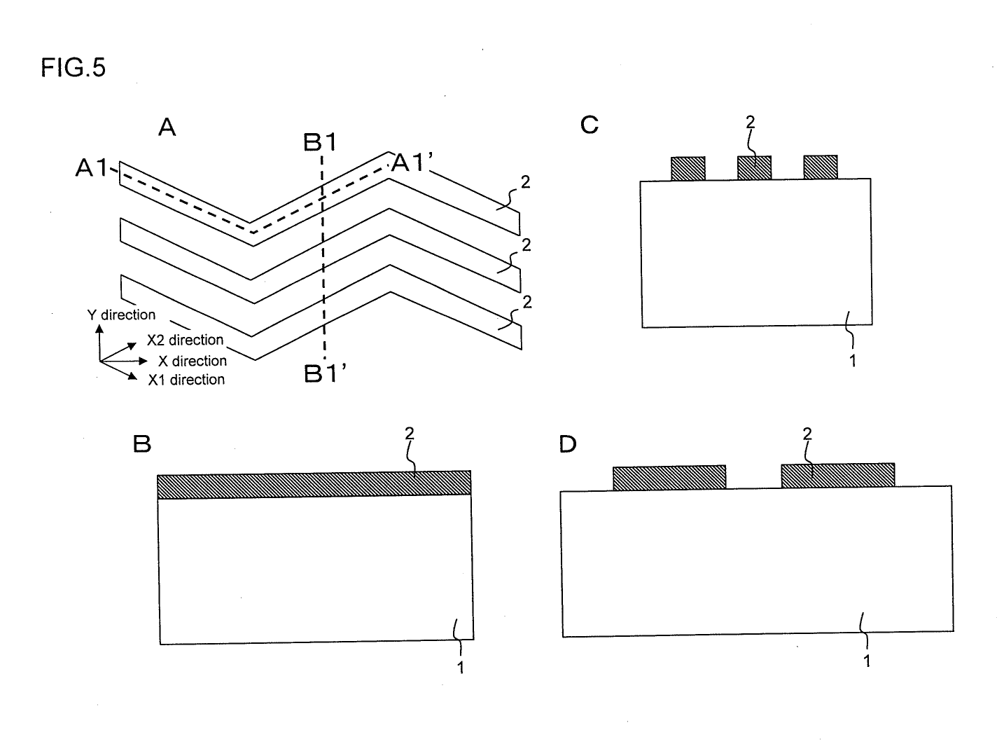

A method for manufacturing a semiconductor device will be now explained with reference to FIGS. 5 to 16. Fig. A is a plane view that is partially extracted from the plane view of the memory cell region shown in FIG. 3. Fig. B is a cross sectional view of A1-A1′ direction in Fig. A, and Fig. C is a cross sectional view of B1-B1′ direction in Fig. A. Fig. D is a cross-sectional view of a peripheral circuit region.

As shown in FIG. 5, a mask 2 is formed on the surface of a substrate, the mask 2 has a band-shaped active region pattern which is curved like a snake, extends to the X direction in a memory cell region and has an active region pattern to be formed a transistor in a peripheral circuit region. A p-type single crystal silicon substrate is used as a substrate 1. A single-layered film, such as a silicon nitride film, an amorphous carbon film, an amorphous silicon film, or a layered film thereof can be used as the mask 2. After forming a silicon oxide film (not shown in the drawings) on the surface of the substrate 1, a mask material is formed on the entire surface of the silicon oxide film. The mask 2 is an active region pattern, is formed in each of the memory cell region and the peripheral circuit region by lithograph and dry etching.

A band-shaped active region pattern formed in the memory cell region is curved like a snake and extends to the X direction, the band-shaped active region pattern has a portion extending to the X1 direction downward to right of the X direction and a portion extending to the X2 direction upward to right of the X direction. The portion extending to the X1 direction is connected to the portion extending to the X2 direction so that the portion extending to the X1 direction and the portion extending to the X2 direction are disposed alternatively and repeated in the X direction.

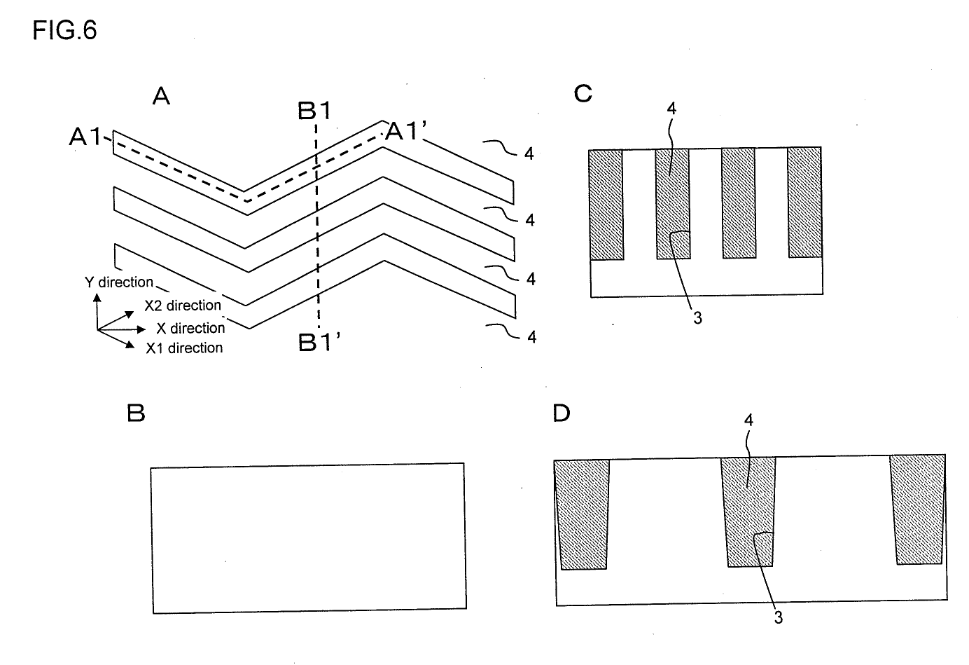

Subsequently, as shown in FIG. 6, a substrate 1 is dry-etched using a mask 2, to form a trench 3 having a depth of 250 to 300 nm. In this embodiment, the depth of the trench 3 is 300 nm. Thereafter, a laminating film comprising a silicon oxide film and a silicon nitride film is buried in the trench 3 and the mask 2 is removed, to form a first isolation region 4. In a memory cell region, a band-shaped active region curved like snake is isolated in the Y direction by the first isolation region 4.

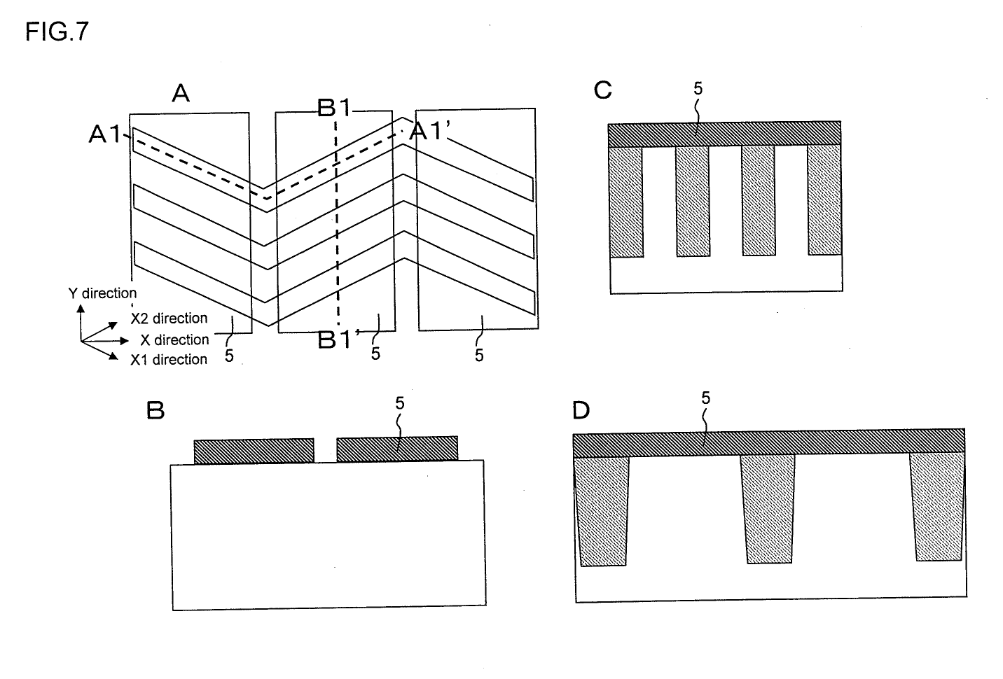

Subsequently, as shown in FIG. 7, a mask 5 isolating a band-shaped active region curved like snake and formed in a memory cell region in the X direction is formed on the surface of a substrate 1. The mask 5 is formed so as to expose a plurality of peaks generated by curving the band-shaped active region. The mask 5 may be made of the same material as mask 2 and is formed by lithography and dry etching.

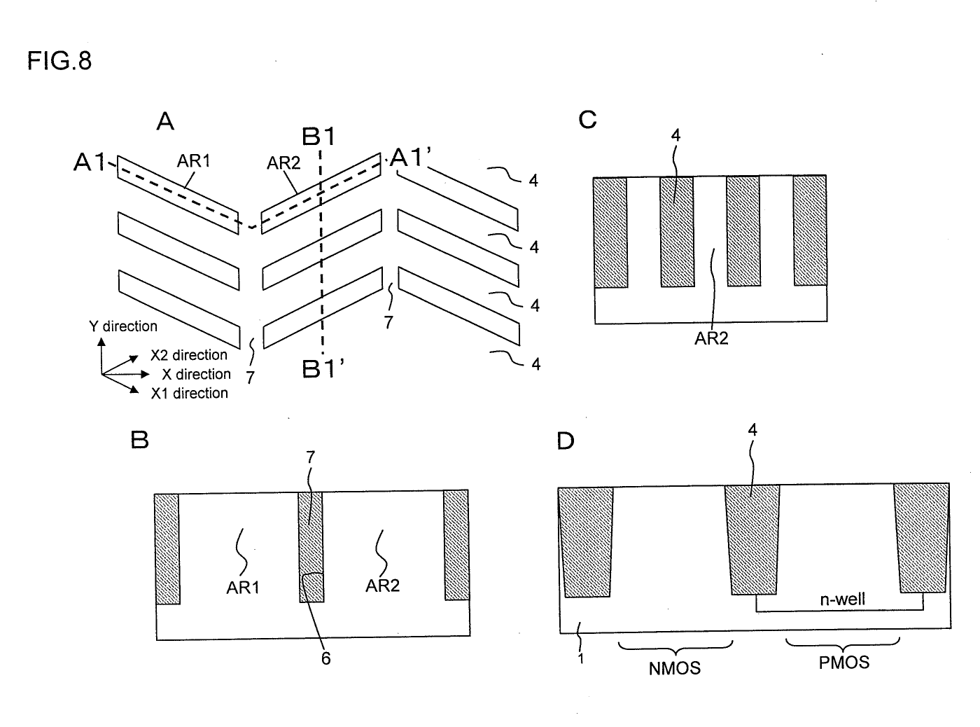

Subsequently, as shown in FIG. 8, a substrate 1, the surface of which is exposed by using a mask 5, and a first isolation region 4 are dry-etched, to form a trench 6 having the same depth as the first isolation region 4. Thereafter, a laminating film comprising a silicon oxide film and a silicon nitride film is buried in the trench 6 and the mask 5 is removed, to form a second isolation region 7. In a memory cell region, a band-shaped active region curved like snake is isolated in the X direction by the second isolation region 7. As a result, a plurality of active regions AR1 and AR2 isolated in the X direction by the isolation region 7 and isolated in the Y direction by the isolation region 4 are formed in the substrate 1 of the memory cell region. The active region AR1 extends to the X1 direction that is inclined at about 30° downward to right in the X direction and is disposed at the same pitch in the Y direction. The active region AR2 extends to the X2 direction that is inclined at about 30° upward to right in the X direction and is disposed at the same pitch in the Y direction. The active regions AR1 and AR2 are alternatively disposed at the same pitch in the X direction. In this embodiment, in the Y direction, each active region has a width of 35 nm and the pitch has a size of 70 nm. Also, in the X direction, each active region has a width of 175 nm and the pitch has a size of 210 nm. This embodiment is a 6F² structure in which the minimum process dimension F is 35 nm. Also, before and after forming the isolation region 7, in the peripheral circuit region, an n-well is formed within the substrate 1 of a PMOS region, in which a p-channel MOS transistor is to be formed. Specifically, a photoresist mask is formed on region other than the PMOS region and boron (B) is ion-injected in the PMOS region.

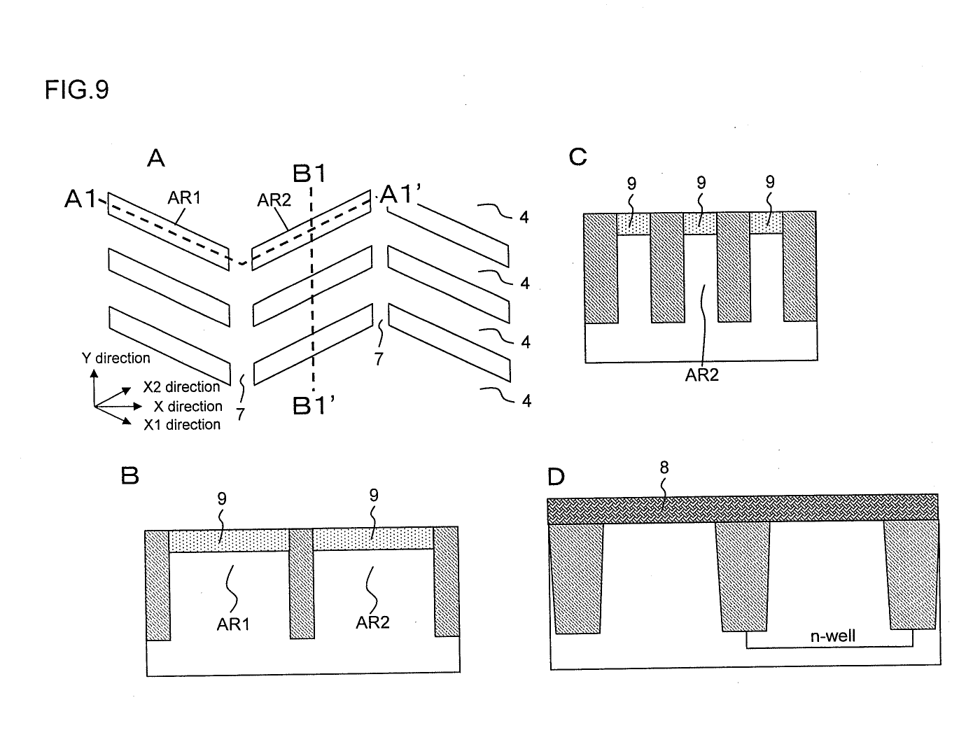

Subsequently, as shown in FIG. 9, a mask made of photoresist and covering a peripheral circuit region is formed. Thereafter, n-type impurity, such as phosphorous (P) is ion-injected onto the entire surface of the substrate, to form an n-type diffusion layer 9 in the surface of active regions AR1 and AR2 in a memory cell region. The n-type diffusion layer 9 ares a source diffusion layer or a drain diffusion layer of a finally formed cell transistor. Thereafter, the mask 8 is removed.

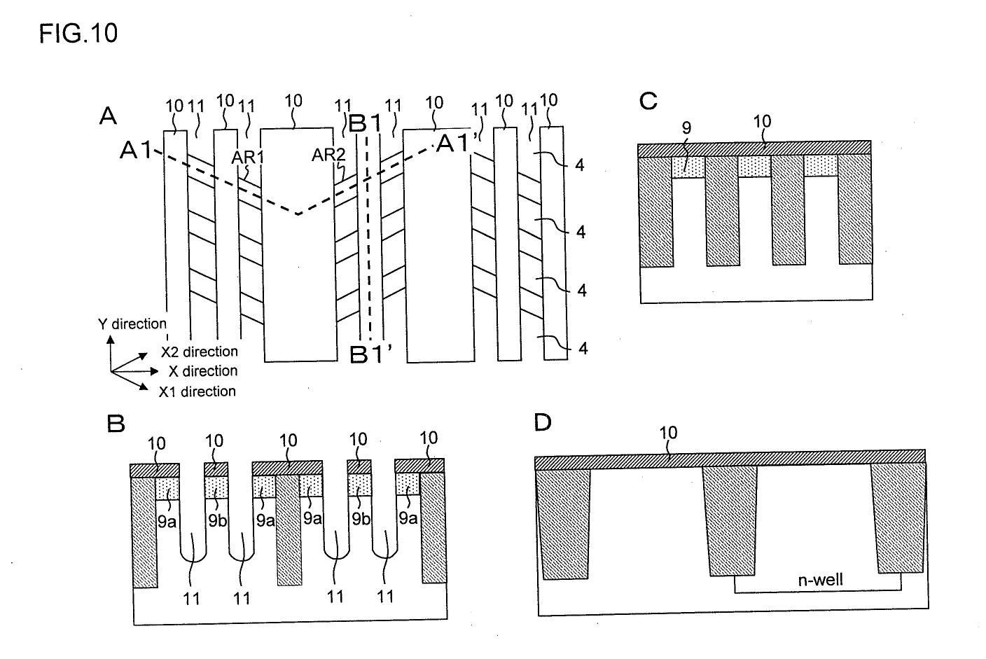

Subsequently, as shown in FIG. 10, a silicon oxide film having a thickness of 40 nm is formed on the entire surface of a substrate 1, and a mask insulating film 10 having a pattern is formed by lithography and dry etching. The pattern exposes a word line region formed in a memory cell region. The word line region is a pattern extending over a plurality of active regions and a first isolation region 4 in the Y direction. Two word line regions are formed in each active region. The width of the word line region is 35 nm in the X direction. Thereafter, the substrate 1 is dry-etched by using the mask insulating film 10, to form a gate trench 11 having a depth of 150 to 200 nm and to be a word line region. In this embodiment, the deepest portion of the gate trench 11 has a depth of 200 nm. As a result, the n-type diffusion layer 9 formed in the process of FIG. 9 is divided into a capacitor diffusion layer 9a connected to a capacitor and a bit line diffusion layer 9b connected to a bit line in the following processes. The thickness of the mask insulating film 10 decreases from 40 nm to 25 nm by dry etching the gate trench 11.

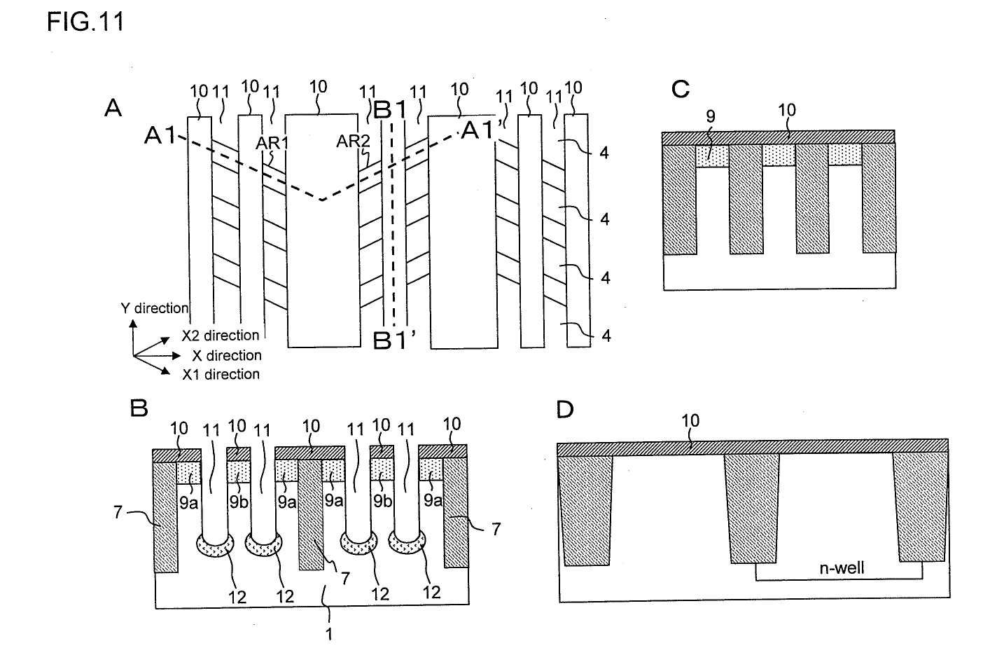

Subsequently, as shown in FIG. 11, an n-type impurity, such as phosphorous, or arsenic (As) is ion-injected on the entire surface of the substrate. As a result, a trench diffusion layer 12 is formed on the substrate surface of the bottom of a gate trench 11. In the deepest portion of the gate trench 11, the trench diffusion layer 12 has a width of 10 to 30 nm in the depth direction. In this embodiment, the width of the trench diffusion layer is 20 nm. If the width of the trench diffusion layer 12 is 35 nm or more in the depth direction, the trench diffusion layer 12 contacts with an adjacent second isolation region 7, thereby becoming a floating body. Therefore, a trench diffusion layer 12 having a width 35 nm or more is not preferable, because it may inhibit operation of a cell transistor. Accordingly, the width of the trench diffusion layer 12 in a depth direction should be adjusted so as to be smaller than the width in the X direction between the gate trench 11 and the second isolation region 7.

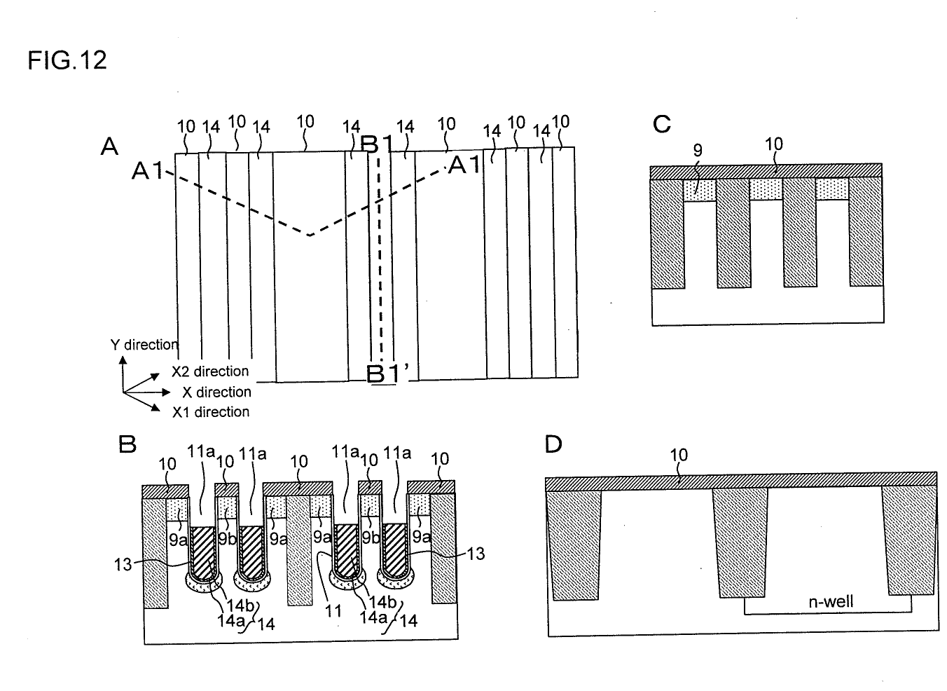

Subsequently, as shown in FIG. 12, a gate insulating film 13 made of a silicon oxide film having a thickness of 5 nm is formed on the inner surface of a gate trench 11 by thermal oxidation. Thereafter, a TiN 14a having a thickness of 5 nm is formed by CVD, and a W film 14b having a thickness of 30 nm is formed by CVD. Since the gate trench 11 is formed so as to have a width of 35 nm in the X direction, the gate trench 11 is completely buried by TiN 14a and W 14b in this process. Thereafter, a laminating film made of TiN 14a and W 14b is dry-etched to form a buried gate electrode 14 made of TiN 14a and W 14b buried in the gate trench 11. The upper surface of the buried gate electrode 14, which buries the bottom portion of the gate trench 11, is formed so as to have a depth in the range ½ to ⅘ of the depth of the deepest portion of the gate trench 11. In this embodiment, the depth is 120 nm, which is ⅗ of the depth of the deepest portion of the gate trench 11. In this embodiment, since the depth of the deepest portion of the gate trench 11 is 200 nm, the upper surface of the buried gate electrode 14 is formed at a position where the depth from the upper surface of a substrate 1 is 80 nm. The buried gate electrode 14 is a word line 4. In this process, the thickness of a mask insulating film 10 decreases from 25 nm to 20 nm by etching back. Also, a new gate trench 11a is formed on the buried gate electrode 14 by forming the buried gate electrode 14 within in the gate trench 11.

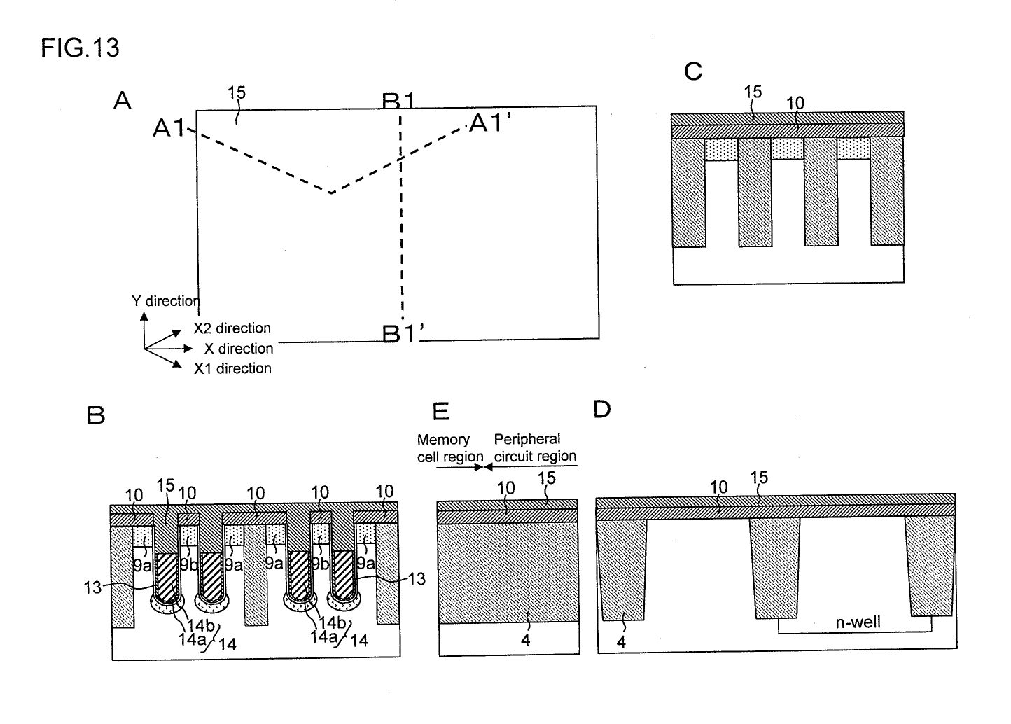

Subsequently, as shown in FIG. 13, a cap insulating film 15 made of a silicon nitride fill having a thickness of 20 nm is formed in the entire surface of the substrate by CVD so as to bury the new gate trench 11a. As a result, in region other than the gate trench 11a, an insulating film having a thickness of 40 nm which is made of a mask insulating film 10 having a thickness of 20 nm and a cap insulating film 15 having a thickness of 20 nm, is formed on the surface of a substrate 1. FIG. 13E is cross sectional view of the boundary between the memory cell region and the peripheral circuit region shown in plane view of FIG. 3. The boundary is disposed on an isolation region 4. A laminating insulating film is formed, as the peripheral circuit region. The laminating insulating film is made of a mask insulating film 10 and a cap insulating film 15, and has a thickness of 40 nm.

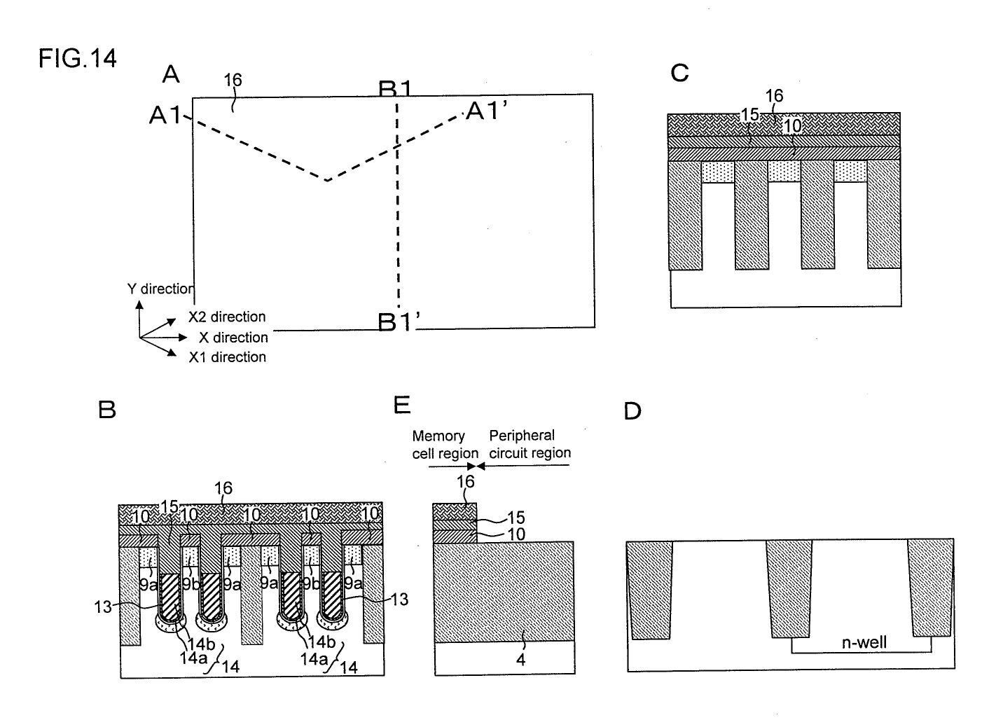

Subsequently, as shown in FIG. 14, a mask 16 made of photoresist is formed in a memory cell region, and a cap insulating film 15 and a mask insulating film 10 exposed in the peripheral circuit region are removed. As a result, an upper surface of the substrate 1 is exposed in the peripheral circuit region. Thereafter, the mask 16 is removed.

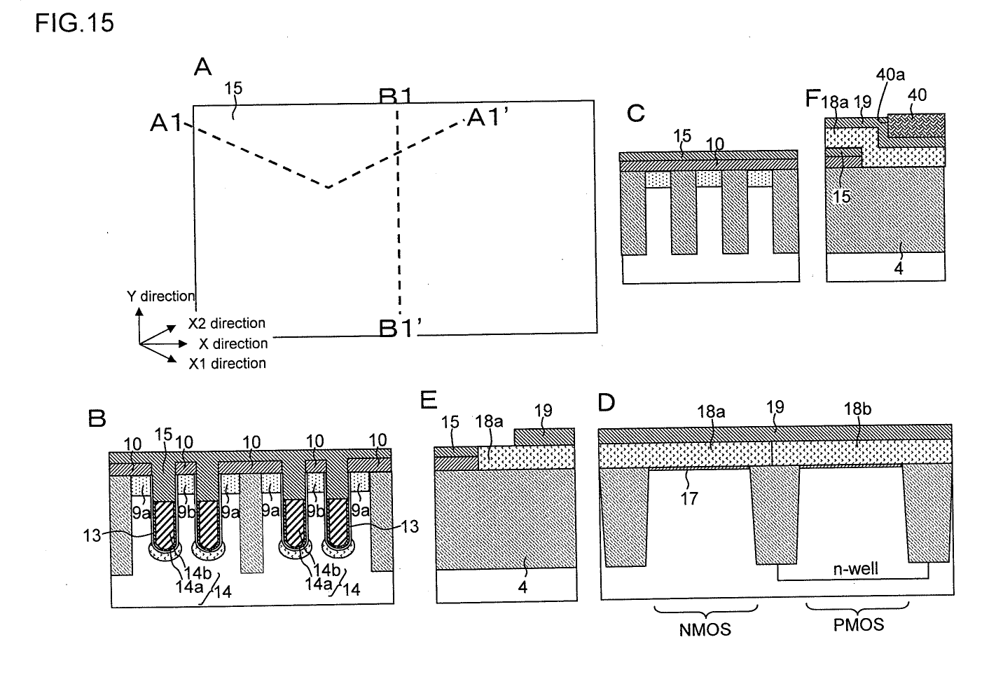

Subsequently, as shown in FIG. 15, a gate insulating film 17 made of a silicon oxide film having a thickness of 4 nm is formed by a thermal oxidation method on the surface of a substrate 1 in a peripheral circuit region. Thereafter, an amorphous silicon film (corresponding to a first silicon film) 18 having a thickness of 40 nm is formed on the entire surface of the substrate 1 by CVD. Further, a silicon oxide film 19 is formed as a protection film. Thereafter, a photoresist pattern (not shown) covering an PMOS region in the peripheral circuit region is formed and P is ion-injected into an amorphous silicon film in the NMOS region by using the photoresist pattern as a mask, to concert the amorphous silicon film into an n-type impurity containing amorphous silicon film 18a. After removing the photoresist pattern, a new photoresist pattern (not shown) having an opening on a PMOS region in the peripheral circuit region is formed and B is ion-injected into an amorphous silicon film in the PMOS region by using the photoresist pattern as a mask, to convert the amorphous silicon film into a p-type impurity containing amorphous silicon film 18b. After removing the photoresist pattern, a new photoresist pattern 40 having an opening on the memory cell region is further formed. FIG. 15F is cross sectional view of the boundary between the memory cell region and the peripheral circuit region after forming photoresist pattern 40. In the boundary, an amorphous silicon film 18a and a silicon oxide film 19 are formed on a cap insulating film 15 formed in the memory cell region so as to cover the cap insulating film 15. In this state, photoresist pattern 40 is formed so that an edge portion 40a of photoresist pattern 40 contacts with a side surface of step made of the silicon oxide 19. Next, the silicon oxide 19 including an exposed upper surface and the amorphous silicon film 18a under the silicon oxide 19 are removed by constant rate dry etching. As a result, the upper surface of the cap insulating film 15 made of a silicon nitride film is exposed in the memory cell region. Thereafter, by removing the photoresist pattern 40, as shown in FIG. 15E, a cross sectional shape of the boundary is formed so that the upper surface of the cap insulating film 15 in the memory cell region is flush with the upper surface of the amorphous silicon film 18 in the peripheral circuit region. Both the silicon oxide film and amorphous silicon film may be dry-etched using fluorine-containing plasma. Therefore, for example, both the silicon oxide film and amorphous silicon film may be etched at constant rate by adjusting gas supply amount of CH₄ and oxygen in a plasma containing CH₄ and oxygen.

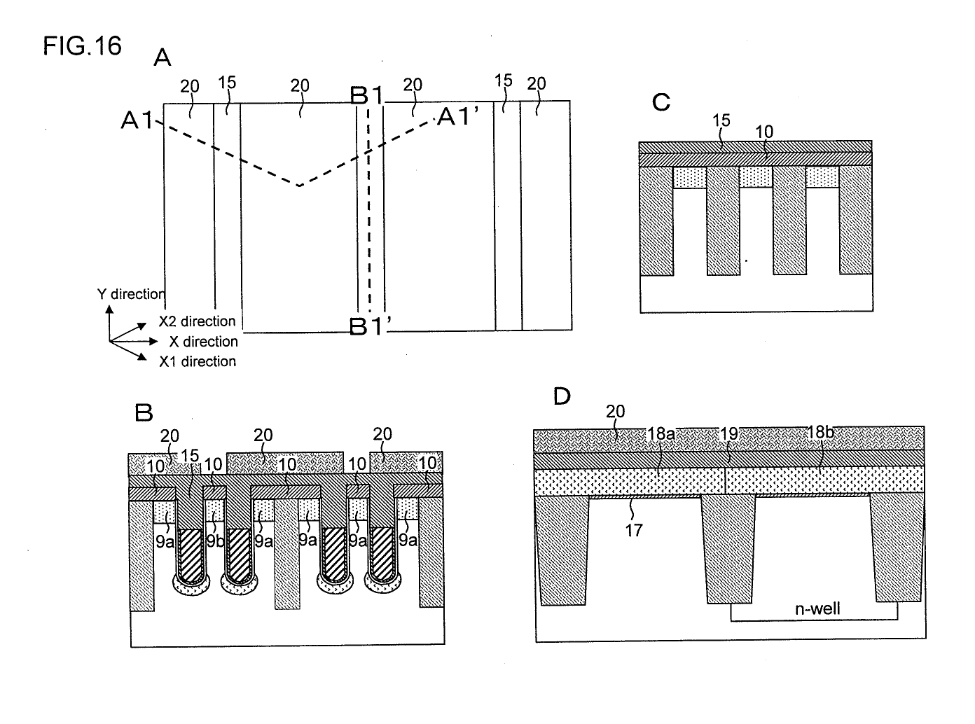

Subsequently, as shown in FIG. 16, a mask 20 having a pattern opened by a line extending to the Y direction is formed above a bit line diffusion layer 9b in a memory cell region.

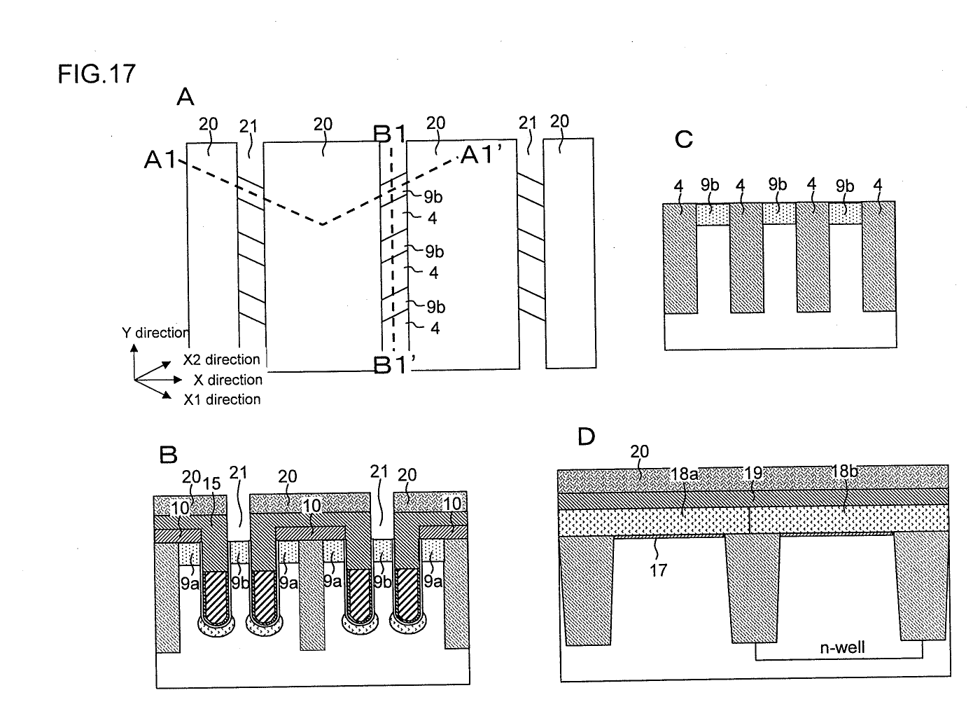

Subsequently, as shown in FIG. 17, a cap insulating film 15, the upper surface of which is exposed, is dry etched by using a mask 20, and continuously, a mask insulating film 10 is dry etched to expose the upper surface of a bit line diffusion layer 9b. In this process, since the cap insulating film 15 is made of a silicon nitride film and the mask insulating film 10 made of a silicon oxide film, it is possible to remove the mask insulating film 10 in a self-aligned manner by liquid etching. In other words, dry etching is stopped in the process where the upper surface of the mask insulating film 10 is exposed by dry etching the cap insulating film 15, and then, the mask insulating film 10, the upper surface of which is exposed, is etched by an HF containing solution. Since the silicon nitride film 15 is be hardly etched in an HF containing solution, it is possible to remove the mask insulating film 10 in a self-aligned manner. As a result, a trench 21 extending to the Y direction is formed on a bit line diffusion layer 9b. On the bottom surface of the trench 21, the bit line diffusion layer 9b and first isolation region 4 are alternatively exposed in the Y direction.

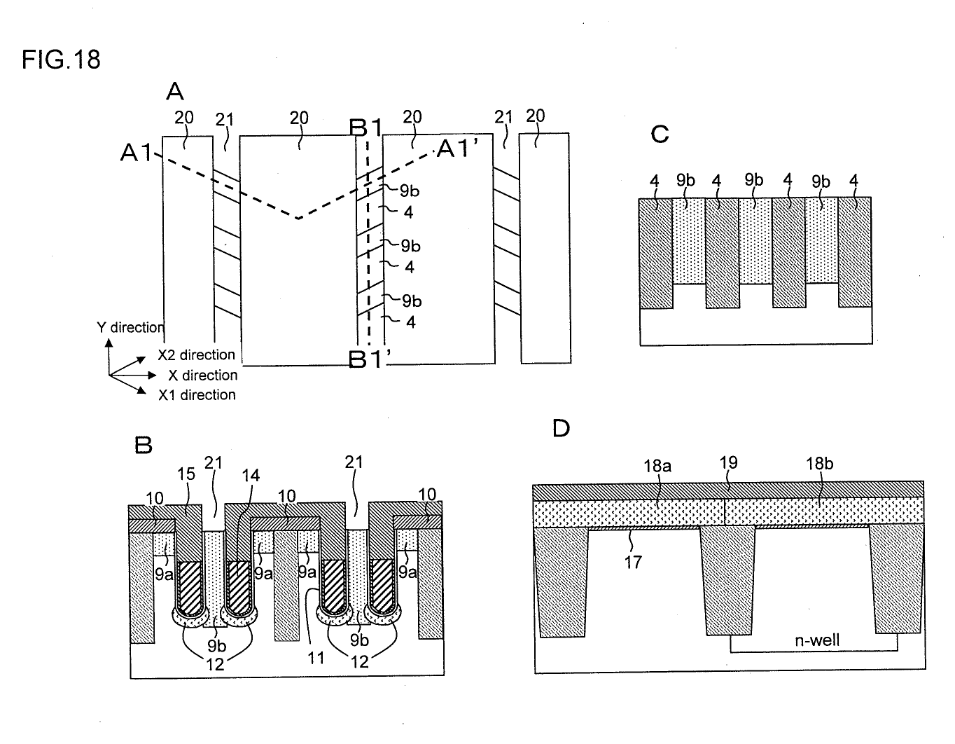

Subsequently, as shown in FIG. 18, a mask 20 is removed. As a result, an opening 21 comprises a cap insulating film 15 for protecting a buried gate electrode 14 as a sidewall. The depth of the opening 21, i.e., the height of the sidewall of the cap insulating film 15, is 40 nm, which is the sum of the thickness of a mask insulating film 10 and the cap insulating film 15.

Thereafter, P is ion-injected onto the entire surface of the substrate by using the cap insulating film 15 as a mask and the bottom surface of a bit line diffusion layer 9b is formed up to a position deeper than the deepest portion of a gate trench 11. The ion injection can be performed in two phases by changing the injection energy. In the first injection phase, the injection energy is selected to place the center of the projected range in the center of the gate trench 11, i.e., 100 nm depth. In the second injection phase, the injection energy is selected to place the center of the projected range in the bottom of the gate trench 11. For accuracy, the ion injection may be performed in three phases. When ion is injected into a deep portion, a cap insulating film sometimes cannot function as a mask, because it is very thin. In this case, it is preferable not to remove the mask 20 used in FIG. 17 and to remove it after finishing the ion injection. As a result, a previously formed adjacent trench diffusion layer 12 is connected to a deeply formed bit line diffusion layer 9b and is integrated with the bit line diffusion layer 9b. After forming the deep bit line diffusion layer 9b, a heat treatment is performed for 10 second at 1000° C. to activate the injected impurity, so that the diffusion layer is converted into an n-type semiconductor. Such heat treatment activates the impurity included in the capacitor diffusion layer 9a, and thus, also converts into an n-type semiconductor. Also, such heat treatment activates the impurity included in the amorphous silicon films 18a, 18b formed in the peripheral circuit region, and thus, converted them into polysilicon film. As a result, they are converted into a polysilicon film 18a which is an n-type semiconductor, and a polysilicon film 18b which is a p-type semiconductor.

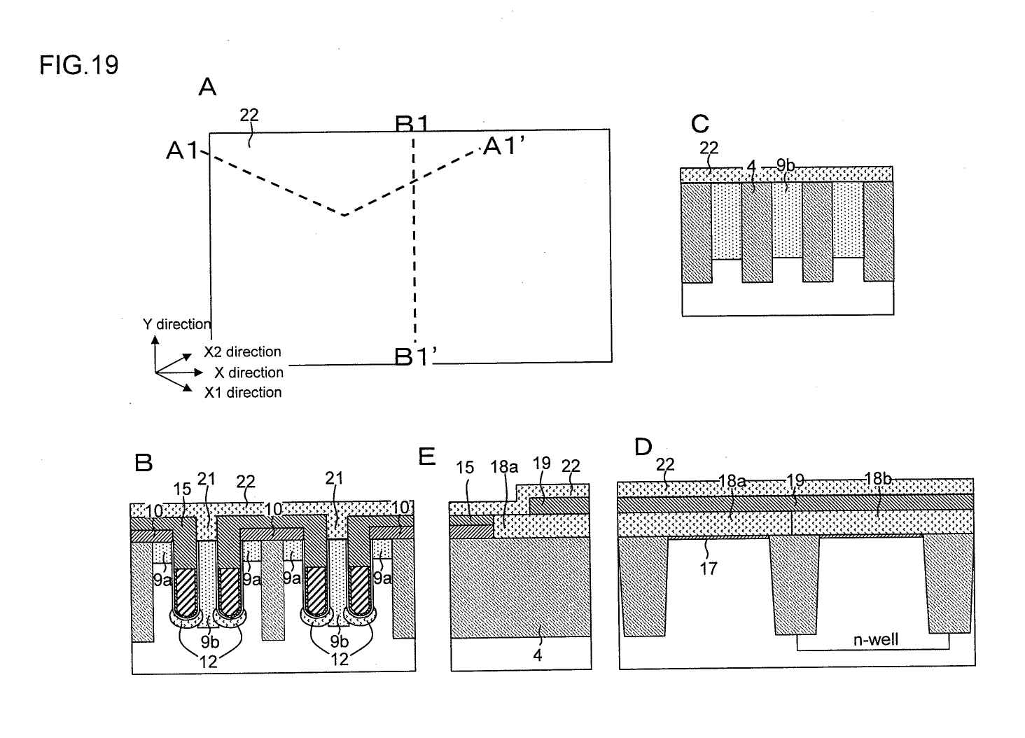

Subsequently, as shown in FIG. 19, an amorphous silicon film (corresponding to a second silicon film) 22 is formed on the entire surface of the substrate by CVD so as to be connected to a bit line diffusion layer 9b, the upper surface of which is exposed within an opening, and so as to fill up the opening 21.

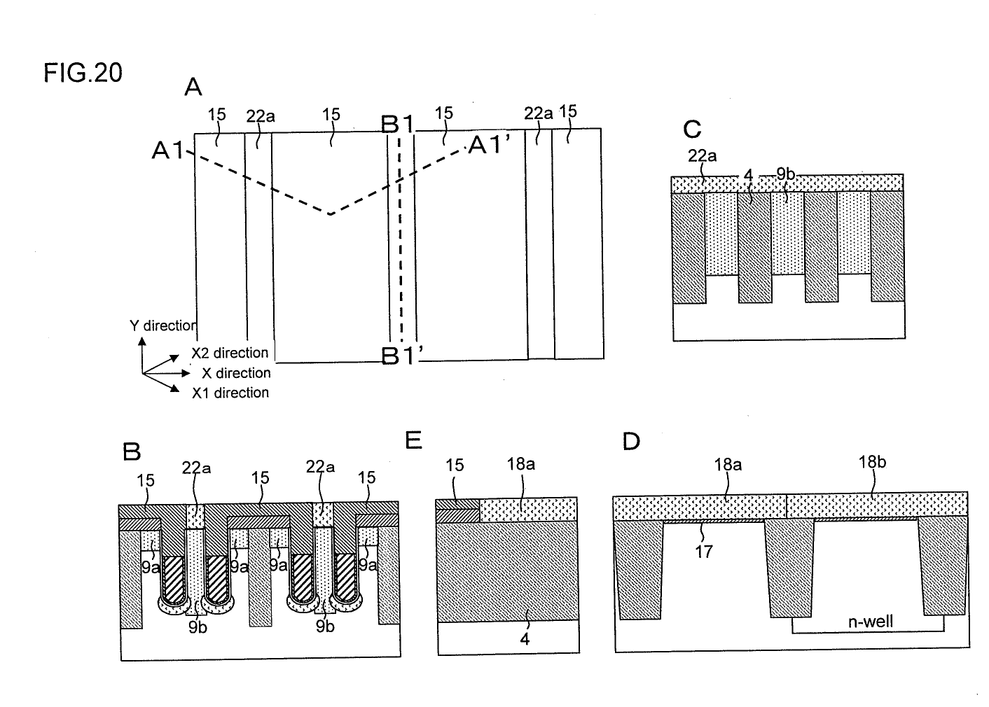

Subsequently, as shown in FIG. 20, an amorphous silicon film 22 is dry etched back so as to form an amorphous silicon film 22a so as to fill up an opening 21. In this process, a silicon oxide film 19 remains in a peripheral circuit region. In this state, P is introduced into the amorphous silicon film 22a by injecting ion on the entire surface. Also, a heat treatment is performed to the amorphous silicon film 22a for 10 second at 1000° C., so that it is polycrystallized and is converted into an n-type semiconductor by activating introduced P. In the process forming the amorphous silicon film 22 by CVD, a P containing amorphous silicon film may be formed. In this case, it is not necessary to introduce P by ion injection, but a heat treatment is necessary. As mentioned above, a heat treatment is performed to the amorphous silicon film for about 10 second at 1000° C., so that it is polycrystallized and is converted into an n-type semiconductor by activating introduced P. As mentioned above, if a heat treatment is performed to an amorphous silicon film while it contains impurity, so that it is converted into a polysilicon film whose resistance is less than the resistance of a film formed in a polysilicon state in a depositing process. Therefore, it is advantageous to reduce contact resistance.

Subsequently, a silicon oxide film 19 remaining in a peripheral circuit region is selectively removed by an HF containing solution. A silicon nitride film 15 or polycrystal films 22a, 18a, 18b are not etched by such liquid etching. In the process in FIG. 15, an amorphous silicon film 18 is formed in the peripheral circuit region so that an upper surface of the amorphous silicon film 18 is deposited at the same height as an upper surface of a cap insulating film 15 formed in the memory cell region. Therefore, in process of FIG. 20, the upper surfaces of the cap insulating film 15 and the poly silicon crystal film 22a are the surface of the memory cell region and are disposed at height of 40 nm form the surface of the substrate 1. The upper surface of polysilicon film 18a, 18b is the surface of the peripheral circuit region and is disposed at height of 40 nm form the surface of the substrate 1. The upper surfaces of the cap insulating film 15 and the poly silicon crystal film 22a are flush with the upper surface of polysilicon film 18a, 18b. If there is a step having a height over 5 nm at a boundary between the memory cell region and the peripheral circuit region, there is a problem that a bit line is disconnected at the step in processing the bit line and a gate electrode in the subsequent processes. Accordingly, it is necessary to form the step having a height of 5 nm or less, at the boundary between the memory cell region and the peripheral circuit region. No step is most preferable at the boundary. During the manufacture of a miniaturized semiconductor device with a bit line having a width of 40 nm or less, such problem remarkably causes. This embodiment is controlled so as to generate no step between the memory cell region and the peripheral circuit region, thereby avoiding such problem and preventing the reduction of production yield.

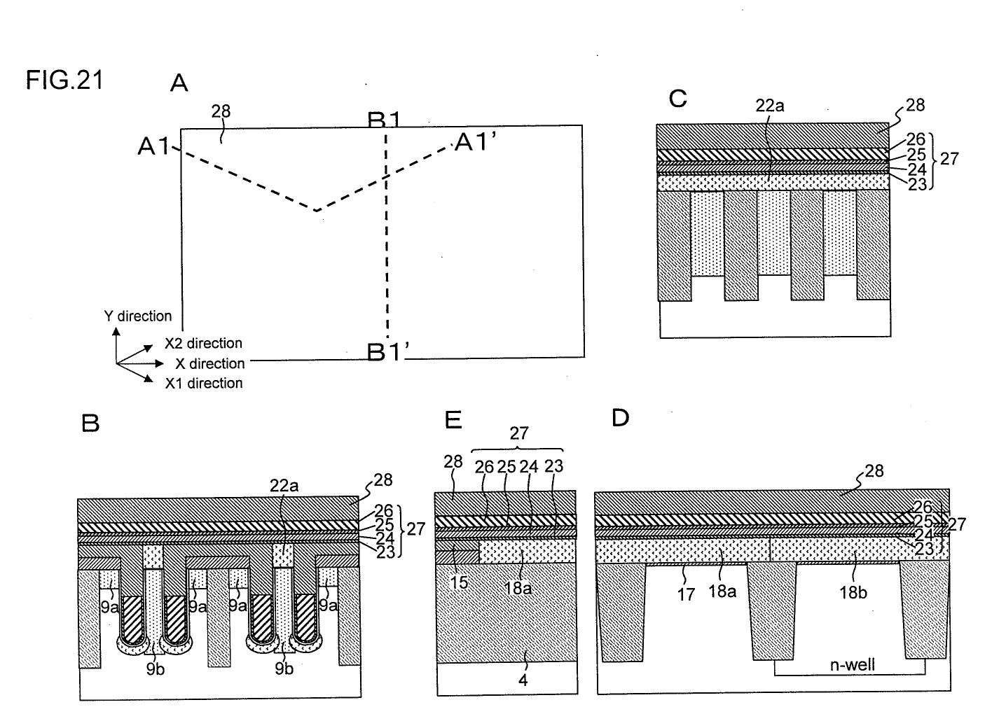

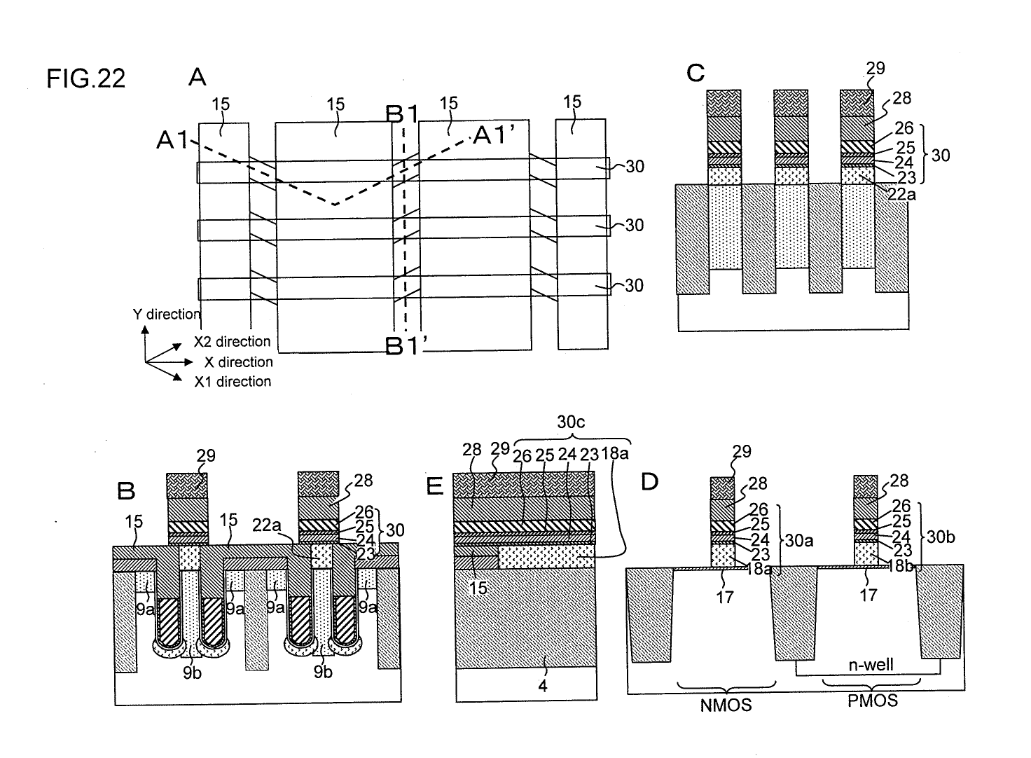

Subsequently, as shown in FIG. 21, while forming the surface of the memory cell region and the surface of the peripheral circuit region at the same height, a metal laminating film 27 is formed by laminating a metal buffer film 23 having a thickness of 2 nm, a TiN film 24 having a thickness of 10 nm, a WSi film 25 having a thickness of 2 nm, and a W film 26 having a thickness of 20 nm in this order on the entire surface of a substrate 1 by PVD. The thickness of the metal buffer film 23 may be in the range of 0.5 to 5 nm. The thickness of the TiN film 24 may be in the range of 1 to 10 nm. The thickness of the WSi film 25 may be in the range of 0.2 to 2 nm. The thickness of the W film 26 may be in the range of 10 to 30 nm. A TiSi film may be used instead of the metal buffer film 23. In this embodiment, since there is no step height between the memory cell region and the peripheral circuit region, there is no problem of step coverage. Therefore, it is not necessary to use CVD and it is possible to form films by PVD. Since all the metal laminating films, from the Ti film 23 to the W film 26, may be formed by PVD, it is possible to form films continuously within one device having multi chambers, without taking out a substrate. As a result, no contaminant adheres to the interface of each conductor and it is possible to keep pure contact between conductors. Thereafter, a cover insulating film 28 made of a silicon nitride film is formed on the W film 26 by CVD. Although the overall metal buffer film is made of the Ti film, the metal buffer film formed on the bit line contact plug 22a, and silicon films 18a, 18b is converted into a TiSi film. However, the metal buffer film 23 formed on the cap insulating film 15 is not converted and the Ti film remains on the cap insulating film 15. Subsequently, as shown in FIG. 22, a mask 29 is formed by lithography and dry etching. A mask 29 has a pattern of a bit line 30 extending to the X direction in a memory cell region, a pattern of a wiring for a peripheral circuit region connected to the bit line 30 in a peripheral circuit region, and a pattern of n-type gate electrode in NMOS region and p-type gate electrode in PMOS region connected to the wiring for the peripheral circuit region in the peripheral circuit region. Photoresist made of amorphous carbon film may be used as the mask film 29. Thereafter, a cover insulating film 28, a W film 26, a WSi film 25, a TiN film 24, and a metal buffer film 23 are etched in this order by using the mask 29. Also, in the memory cell region, a polysilicon film 22a, which is disposed between adjacent bit lines in Y direction and buried in an opening 21, is etched, and in the peripheral circuit region, polysilicon films 18a, 18b are etched. As a result, in the memory cell region, a bit line contact plug 22a is interposed to form a bit line 30 connected to a bit line diffusion layer 9b, and in the peripheral circuit region, an n-type gate electrode 30a made of an n-type silicon film 18a and a metal laminating film are formed, and a p-type gate electrode 30b made of a p-type silicon film 18b and a metal laminating film are formed. At the same time, a wiring 30c for a peripheral circuit region connecting each gate electrode to a bit line 30 is formed. The bit line 30 is made of only the metal laminating film in portion other than portion on the bit line contact plug 22a, while each gate electrode and wiring for a peripheral circuit region are made of poly-metal structure in which the metal laminating film is formed on a silicon film.

In this embodiment, since a silicon film connecting the bit line 30 to bit line diffusion layer 9b is formed as a bit line contact plug 22a, which is inserted into a cap insulating film 15, the bit line 30 extending to the X direction is made of only a metal conductor of a W film 26, a WSi film 25, a TiN film 24, and a metal buffer film 23 in portion other than portion connected to the bit line contact plug 22a, and does not comprise a polysilicon film as component of the bit line. Therefore, it is possible to reduce the height of the bit line 30, thereby reducing the parasitic capacitance of the bit line 30. The detection sensitivity of accumulation charge in a DRAM is determined by balance between the capacity of a capacitor and the parasitic capacitance of a bit line. When the parasitic capacitance of a bit line increases, it is difficult to operate a DRAM, if the capacity of a capacitor does not increase accordingly. In this embodiment, the parasitic capacitance of a bit line can be reduced, it can provide a DRAM operable even when it is miniaturized and thus has a smaller capacitor capacity.

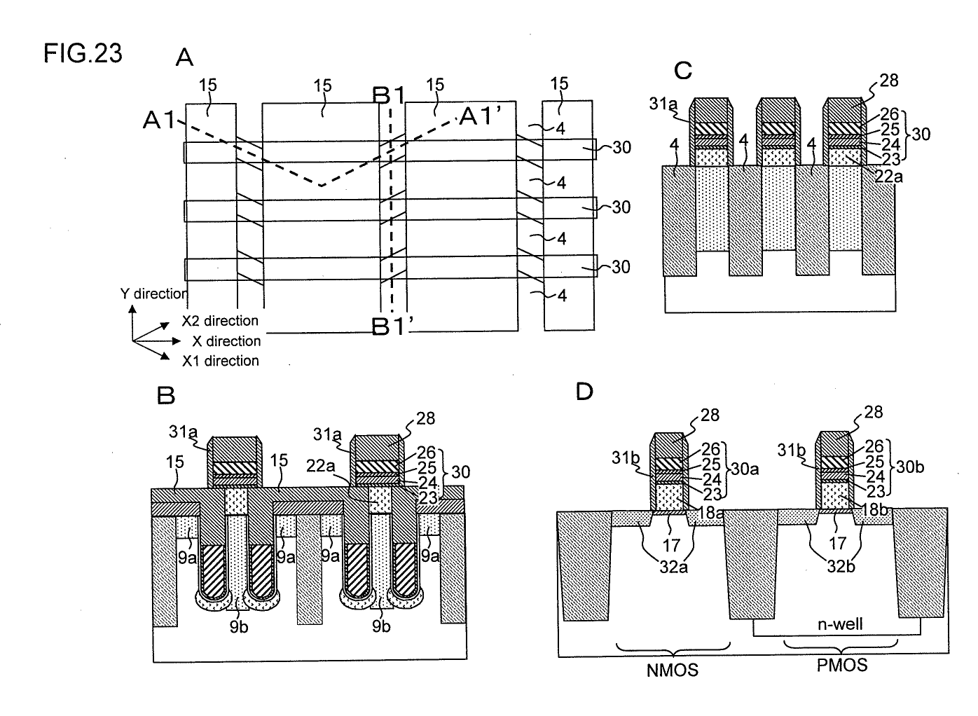

Subsequently, as shown in FIG. 23, after removing a mask 29 in a memory cell region, a sidewall insulating film 31a made of a silicon nitride film for protecting a sidewall of a bit line is formed. Also, in the peripheral circuit region, a sidewall 31b for protecting a sidewall of a gate electrode is formed. A source/drain diffusion layers made of an n-type impurity diffusion layer 32a are formed in an NMOS region, and a source/drain diffusion layers made of a p-type impurity diffusion layer are formed in a PMOS region

As shown in FIGS. 4A and 4B, after forming a first interlayer insulating film 33, a capacitor contact plug 34, a lower electrode 35 of a capacitor, a capacitor insulating film (not shown), an upper electrode 36, a second interlayer insulating film 37, a contact plug 38, and an upper wiring 39 are formed in this order in a memory cell region. A first interlayer insulating film 33, a source/drain contact plug 34a, a wiring 35a, a third interlayer insulating film 37a, a contact plug 38a, and an upper wiring 39a are formed in a peripheral circuit region. A DRAM including the memory cell region and the peripheral circuit region is formed.

In this embodiment, a metal laminating film 27 comprises a metal buffer film made of a Ti film 23, a TiN film 24, a WSi film 25, and a W film 26. However, the Ti film 23 is a Ti film, when it is formed by PVD, but a Ti film 23 formed on a silicon film is converted into a Ti silicide (TiSi) film by reacting with silicon by a heat treatment during manufacturing DRAM. Therefore, in the final structure, the Ti film on a bit line contact plug 22a of the memory cell region and the Ti film on a silicon film 18 in the peripheral circuit region are converted into TiSi films. The Ti film 23 included in a bit line 30 formed on a cap insulating film 15 in the memory cell region remains a Ti film 23 in the final structure. Therefore, the bit line 30 comprises a Ti film 23, a TiN film 24, a WSi film 25, and a W film 26. However, at portion other than position on the bit line contact plug 22a, the bit line 30 on the bit line contact plug 22a, and gate electrodes 30a, 30b in the peripheral circuit region, and a portion of a wiring 30c for a peripheral circuit region comprise a TiSi film, a TiN film 24, a WSi film 25, and a W film 26. If a TiSi film 23 is formed, instead of a Ti film 23, the bit line 30 comprises a TiSi film 23, a TiN film 24, a WSi film 25, and a W film 26 over all the regions.

According to this embodiment, silicon films 18a, 18b, which are the lowest layers of gate electrodes 30a, 30b and a wiring 30c for a peripheral circuit region formed in a peripheral circuit region, are formed after forming a cap insulating film 15 included in a memory cell region. Therefore, the silicon film 18 may be formed so as to have substantially the same thickness as the sum of the thickness of a mask insulating film 10 and the thickness of a cap insulating film 15 formed in the memory cell region. As a result, before forming a metal laminating film, it is possible to prevent a step between the memory cell region and the peripheral circuit region from generating. Accordingly, due to no step, it is possible to prevent a bit line 30 connecting the memory cell region to the peripheral circuit region, i.e., step of a metal laminating film from being disconnected. Also, it is possible to form a metal laminating film comprising a metal buffer film 23, a TiN film 24, a WSi film 25, and a W film 26 on a plane which is entirely flat. Therefore, it is not necessary to form films by a CVD device which forms only one material. It is possible to continuously form films within one device, without taking out a substrate. As a result, it is possible to avoid the unevenness of interfacial resistance that is caused due to the presence of contaminant in the interface between the materials of the gate electrodes 30a, 30b formed in the peripheral circuit region.

Also, in a conventional gate electrode structure, a metal laminating film comprising a WSi film, a WN film, and a W film is formed on a silicon film by CVD. During a heat treatment performed to manufacture such conventional gate electrode, impurity in the silicon film diffuses from the WSi film to the WN film toward thickness direction thereof and is captured into the WN film, and thus, the concentration of the impurity in the silicon film reduces, resulting in depleting the gate electrode. Also, there was a problem that the threshold voltage of an MOS transistor including the above gate electrode becomes higher than a measurement value and unevenness of the threshold voltage increases. There was another problem, i.e., unbalanced operation between an NMOS transistor and a PMOS transistor of a sensor amplifier included in the peripheral circuit region increases due to the increase of unevenness in interfacial resistance and threshold current, and thus, the sense sensitivity reduces. However, this embodiment can avoid the problems above, because the metal laminating film in this embodiment comprises a metal buffer film made of a Ti film 23, a TiN film 24, a WSi film 25, and a W film 26.

A first metal is not limited to tungsten and is preferably a refractory metal. The refractory metal is at least one selected from the group consisting of tungsten, cobalt, nickel, and tantalum.

### Second Exemplary Embodiment

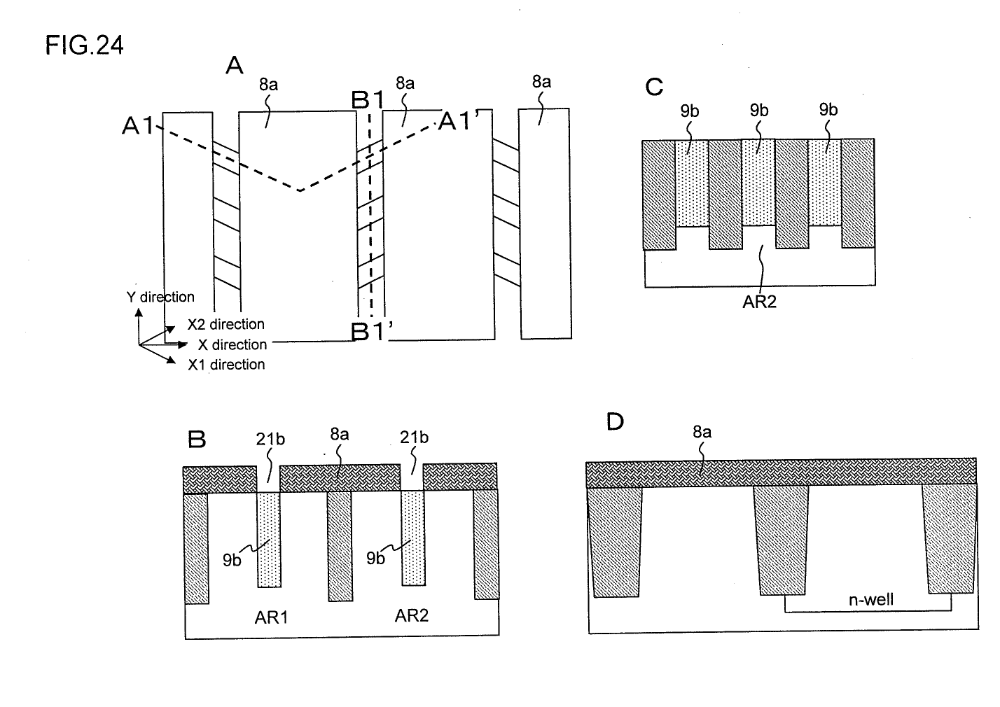

According to the first exemplary embodiment, in the process in FIG. 16, after a trench gate 11 is formed, a buried gate electrode 14 is formed, and a cap insulating film 15 is formed, an opening 21 is formed and then a deep bit line diffusion layer 9b is formed by ion injection. In this embodiment, a method for manufacturing a semiconductor device which comprises forming a deep bit line diffusion layer 9b before forming a gate trench 11. It will be explained now with reference to FIGS. 24 to 26.

First, in accordance with the processes in FIGS. 5 to 8, a first isolation region 4 curved like a snake and extending to the X direction and a second isolation region 7 extending to the Y direction are formed, and a plurality of island-like separate active regions AR1 and AR2 are formed. Subsequently, as shown in FIG. 24, a mask 8a which comprises an opening 21b extending to the Y direction and exposing a bit line diffusion layer in a plurality of the active regions, is formed. A laminating film, in which an amorphous carbon film is laminated on a silicon oxide film, is used as the mask 8a. Thereafter, P is ion-injected onto the entire surface of the substrate by using the mask 8a, and a bit line diffusion layer 9b is formed on a substrate, exposed within the opening 21b. As in the first exemplary embodiment, the bottom surface of the bit diffusion layer 9b is formed so as to be located deeper than the deepest portion of a gate trench 11 that is to be formed in the following processes. Ion injection can be performed at two phases by changing the injection energy. In the first injection phase, the injection energy is selected so as to place the center of the projected range in the center of the gate trench 11, i.e., 100 nm depth. In the second injection phase, the injection energy is selected so as to place the center of the projected range in the bottom surface of the gate trench 11. For accuracy, it is possible to perform the ion injection in three phases.

Also, since an impurity diffusion layer is not formed in other regions of a substrate 1, this process may further perform, for example, a heat treatment for two hours at 900° C. Therefore, it is possible to use a method for thermally diffusing injected impurity to a position deeper than the bottom surface of the gate trench 11 by ion-injecting at relatively low injection energy so that the center of the projected range is deposited at a portion around the center of the gate trench 11, and thereafter, performing a heat treatment. Such heat treatment activates the impurity. If a heat treatment is performed when the impurity diffusion layer had been already formed in other regions of the substrate 1, the thickness of a previously formed impurity diffusion layer becomes thicker. Therefore, it is preferable to perform a heat treatment when the impurity diffusion layer is not already formed in other regions of the substrate 1.

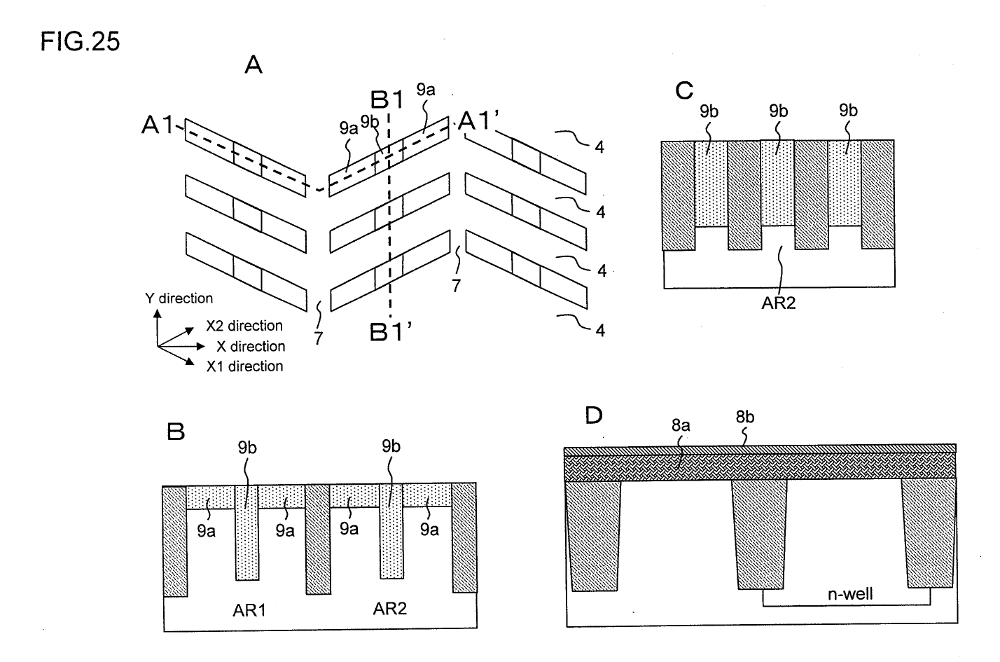

Subsequently, as shown in FIG. 25, a mask 8a formed in a peripheral circuit region is covered with a protection film 8b made of a thin silicon oxide film having a thickness of 5 nm, and then, a mask 8a formed in the memory cell region is removed. Thereafter, P is ion-injected onto the entire surface, to form a capacitor diffusion layer 9a on the surface of a substrate 1 of the substrate. Thereafter, the injected P is activated by a short heat treatment, for example, for 10 seconds at 1000° C. If a deep bit line diffusion layer 9b is formed only by ion injection, the injected P is activated simultaneously with such heat treatment. By the heat treatment for 10 second at 1000° C., the depth of a diffusion layer hardly changes and there is no effect on the properties of a semiconductor device.

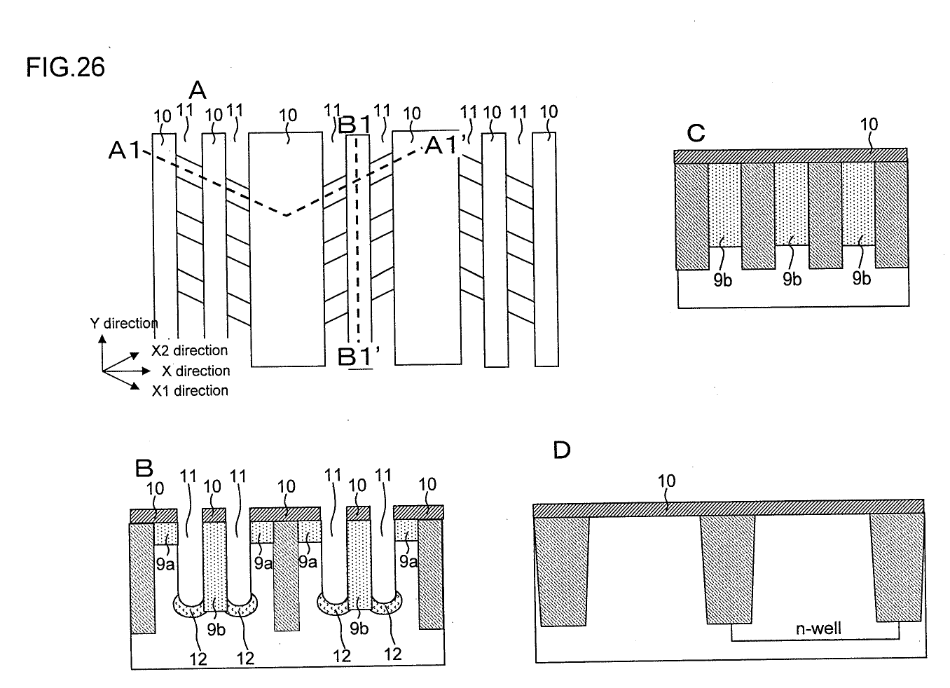

Subsequently, as shown in FIG. 26, after removing masks 8a, 8b formed in a peripheral circuit region, as in the first exemplary embodiment, a silicon oxide film having a thickness of 40 nm is formed on the entire surface of a substrate 1, and a mask insulating film 10 comprising a pattern, which exposes a word line region (buried gate electrode formation region) formed within a memory cell region, is formed by lithography and dry etching. Thereafter, the substrate 1 is etched by using the mask insulating film 10, to form a gate trench 11 having a depth of 200 nm, which is the word line region. Thereafter, n-type impurity such as phosphorus, or arsenic (As) is ion-injected onto the entire surface of the substrate. After the ion injection, the impurity is activated by for example, a heat treatment for 10 second at 1000° C., to form a trench diffusion layer 12 below in the bottom surface of the gate trench 11. The heat treatment is not separately performed to form a bit line diffusion layer 9b and a capacitor diffusion layer 9a, and the heat treatment for forming the bit line diffusion layer 9b and the capacitor diffusion layer 9a may be performed simultaneously with the heat treatment of the trench diffusion layer 12.

The following process may be performed according to the process in FIG. 12 of the first exemplary embodiment. Since it is not necessary to form a deep bit line diffusion layer 9b, the process in FIG. 18 may be omitted.

In the first exemplary embodiment, trench diffusion layers 12 is connected to a bit line diffusion layer 9b and is integrated with it by forming the trench diffusion layers firstly and forming the deep bit line diffusion layer 9b later. However, in this embodiment, trench diffusion layers 12 are connected to a bit line diffusion layer 9b and is integrated with it by forming the deep bit line diffusion layer 9b firstly and forming the trench diffusion layers 12 later.

In the first exemplary embodiment, when forming a deep bit line diffusion layer 9b, a capacitor diffusion layer 9a or an impurity containing polycrystal film for gate electrodes 30a, 30b formed in a peripheral circuit region has been already formed. Therefore, if a heat treatment for 10 second at 1000° C. is performed to form the deep bit line diffusion layer 9b, B contained in a p-type silicon film 18b formed in the peripheral circuit region may be leaked to the surface of a substrate 1 through a gate insulating film 17. Otherwise, if a heat treatment for about 2 hours at 900° C. is performed to form the deep bit line diffusion layer 9b, the depth of the capacitor diffusion layer 9a is too deepen, and thus, the desired properties of a transistor may not be obtained. Since in this embodiment, the deep bit line diffusion layer 9b is formed firstly, it is possible to avoid adverse effects of heat treatment on other elements.

### Third Exemplary Embodiment

This embodiment relates to a semiconductor device comprising one MOS transistor in a peripheral circuit region. The semiconductor device according to this embodiment comprises a memory cell region and a peripheral circuit region. However, for convenience, only a MOS transistor in the peripheral circuit region will be explained.

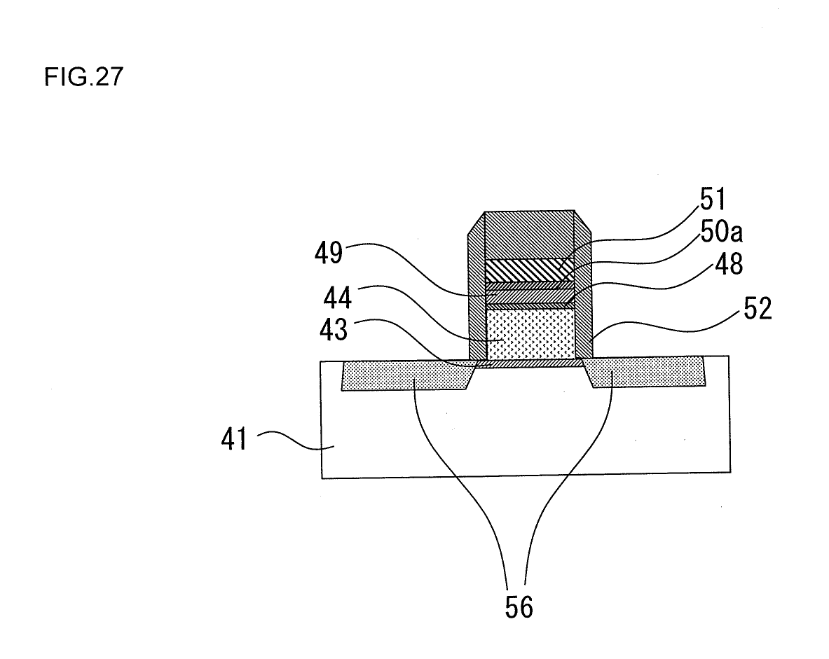

FIG. 27 shows a semiconductor device according to this embodiment. As shown in FIG. 27, a gate insulating film 43 and a gate electrode are formed on a substrate 41. In the substrate 41, source and drain diffusion layers 56 are formed in opposite sides of the gate electrode. In a sidewall of the gate electrode, a sidewall 52 is formed. The MOS transistor comprises a gate insulating film 43, a gate electrode, and source and drain diffusion layers 56.

The gate electrode comprises an impurity containing polysilicon film 44, a TiSi film 48, a TiN film 49, a silicide film 50a of a first metal, and a first metal film 51 in order on the gate insulating film 43. Since the TiSi film 48 and TiN film 49 are formed on the polysilicon film, it is possible to prevent the impurity in the poly-crustal silicon film from diffusing to the silicide film of a first metal during a heat treatment in the following processes. As a result, it is possible to prevent the gate electrode from be depleted, prevent the threshold voltage of the MOS transistor from becoming higher than a measurement value, and prevent unevenness of the threshold voltage from increasing. Also, it is possible to reduce the specific resistance of the gate electrode, because the silicide film of a first metal is formed.

The MOS transistor may be an n-type MOS transistor or a p-type MOS transistor. For example, an n-channel MOS transistor may be made by forming an n-type impurity containing N-type polysilicon film, a substrate comprising a P-well, and an N-type source and drain diffusion layers. Also, a p-channel MOS transistor may be made by forming a p-type impurity containing P-type polysilicon film, a substrate comprising a N-well, and a P-type source and drain diffusion layers. Both the n-channel MOS transistor and the p-channel MOS transistor can effectively prevent the impurity in the polysilicon film from diffusing to the silicide film 50a of a first metal by forming a TiSi film 48 and a TiN film 49 in the gate electrode.

It is preferable to deposit an amorphous silicon film which has no unevenness on its surface and is suitable for miniaturized processing, and then to crystallize it in the following heat treatment, thereby converting it into the polysilicon film 44. A first metal is preferably a refractory metal. The refractory metal is at least one selected from the group consisting of tungsten, cobalt, nickel, and tantalum.

It is apparent that the present invention is not limited to the above embodiments, but may be modified and changed without departing from the scope and spirit of the invention.

In addition, while not specifically claimed in the claim section, the applications reserve the right to include in the claim section at any appropriate time the following method:

1. A method for manufacturing a semiconductor device, comprising:

forming an active region isolated by an isolation region, respectively, in a memory cell region and a peripheral circuit region in a semiconductor substrate;

forming a mask insulating film including an opening pattern crossing the active region in the memory cell region, on an upper surface of the semiconductor substrate;

etching the semiconductor substrate using the mask insulating film as a mask, to form a gate trench;

forming a buried gate electrode which is a word line in the gate trench;

forming a cap insulating film so as to cover the buried gate electrode and the mask insulating film;

forming a first silicon film having substantially the same thickness as sum of a thickness of the mask insulating film and a thickness of the cap insulating film, in the peripheral circuit region;

removing a portion of the mask insulating film and a portion of the cap insulating film, to form an opening exposing a surface of the active region adjacent to the gate trench;

burying a second silicon film in the opening;

forming a metal laminating film over entire surface of the semiconductor substrate; and

removing the metal laminating film partly so that a portion of the metal laminating film contacts with the first and second silicon films, to form a metal laminating wiring extending over the memory cell region and the peripheral circuit region.

2. The method according to the above 1,

wherein in forming the first silicon film, the first silicon film is formed so that a difference between a first thickness and a second thickness is 5 nm or less,

wherein the first thickness is a thickness of the first silicon film, and

wherein the second thickness is sum of the thickness of the mask insulating film and the thickness of the cap insulating film.

3. The method according to the above 1,

wherein in burying the second silicon film, a bit line contact plug is formed.

4. The method according to the above 3,

wherein in removing the metal laminating film partly,

a bit line is formed as the metal laminating wiring in the memory cell region, and

a portion of a wiring for the peripheral circuit region connected to the bit line and a portion of a gate electrode connected to the wiring for the peripheral circuit region are formed as the metal laminating wiring, in the peripheral circuit region.

5. The method according to the above 4,

wherein in forming the first silicon film, the first silicon film containing an n-type impurity and the first silicon film containing a p-type impurity are formed,

in removing the metal laminating film partly, a first gate electrode and a second gate electrode are formed in the peripheral circuit region, the first gate electrode comprising the metal laminating wiring and the first silicon film which contains the n-type impurity below the metal laminating wiring, and the second gate electrode comprising the metal laminating wiring and the first silicon film which contains the p-type impurity below the metal laminating wiring, and

the method further comprises forming an n-channel MOS transistor including the first gate electrode and a p-channel MOS transistor including the second gate electrode.

6. The method according to the above 1,

wherein in forming the metal laminating film, a titanium film, a titanium nitride film, a silicide film of a first metal, and a first metal film are formed in this order from the semiconductor substrate.

7. The method according to the above 6,

wherein in forming the metal laminating film, the titanium film, the titanium nitride film, the silicide film of the first metal, and the first metal film are formed in a same device.

8. The method according to the above 6,

wherein the first metal is a refractory metal.

9. The method according to the above 8,

wherein the first metal is tungsten, cobalt, nickel, or tantalum.

10. The method according to the above 1,

wherein before burying the second silicon film, the method further comprises forming first and second impurity diffusion layers in the active region in the memory cell region in opposite sides of the gate trench, and

in removing the portion of the mask insulating film and the portion of the cap insulating film, the opening is formed so as to expose the first impurity diffusion layer.

11. The method according to the above 10,

wherein in forming the first and second impurity diffusion layers, the first impurity diffusion layer is formed from the upper surface of the semiconductor substrate to a deeper position than the gate trench.

12. The method according to the above 1,

wherein in forming the first silicon film, an amorphous silicon film is formed, and

the method further comprises converting the amorphous silicon film into a polysilicon film by heat treatment.

13. A method for manufacturing a semiconductor device, comprising:
forming a metal laminating wiring extending over a memory cell region and a peripheral circuit region above a semiconductor substrate, so that a height of a bottom surface of the metal laminating wiring disposed in the memory cell region, from an upper surface of the semiconductor substrate is substantially the same as the height of the bottom surface of the metal laminating wiring disposed in the peripheral circuit region, from the upper surface of the semiconductor substrate,

wherein the metal laminating wiring is a bit line in the memory cell region, and

the metal laminating wiring is a portion of a wiring for the peripheral circuit region connected to the bit line and a portion of a gate electrode connected to the wiring for the peripheral circuit region in the peripheral circuit region.

14. The method according to the above 13,

wherein in forming the metal laminating wiring, a difference between a first height and a second height is 5 nm or less,

wherein the first height is the height of the bottom surface of the metal laminating wiring disposed in the memory cell region, from the upper surface of the semiconductor substrate, and

wherein the second height is the height of the bottom surface of the metal laminating wiring disposed in the peripheral circuit region, from the upper surface of the semiconductor substrate.

15. The method according to the above 13,

wherein in forming the metal laminating wiring, a titanium film, a titanium nitride film, a silicide film of a first metal, and a first metal film are formed in this order from the semiconductor substrate.

16. The method according to the above 15,

wherein in forming the metal laminating wiring, the titanium film, the titanium nitride film, the silicide film of the first metal, and the first metal film are formed in a same device.

17. The method according to the above 15,

wherein the first metal is a refractory metal.

18. The method according to the above 17,

wherein the first metal is tungsten, cobalt, nickel, or tantalum.

1. A semiconductor device, comprising:
a memory cell region and a peripheral circuit region on a semiconductor substrate; and
a metal laminating wiring extending over the memory cell region and the peripheral circuit region,
wherein the metal laminating wiring is a bit line in the memory cell region,
the metal laminating wiring is a portion of a wiring for the peripheral circuit region connected to the bit line and a portion of a gate electrode connected to the wiring for the peripheral circuit region, in the peripheral circuit region, and
a height of a bottom surface of the metal laminating wiring disposed in the memory cell region, from an upper surface of the semiconductor substrate is substantially the same as the height of the bottom surface of the metal laminating wiring disposed in the peripheral circuit region, from the upper surface of the semiconductor substrate.

2. The semiconductor device according to claim 1,
wherein a difference between a first height and a second height is 5 nm or less,
wherein the first height is the height of the bottom surface of the metal laminating wiring disposed in the memory cell region, from the upper surface of the semiconductor substrate, and
wherein the second height is the height of the bottom surface of the metal laminating wiring disposed in the peripheral circuit region, from the upper surface of the semiconductor substrate.

3. The semiconductor device according to claim 1,
wherein the memory cell region further comprises a bit line contact plug which includes a polysilicon film connected to the bit line and containing an impurity.

4. The semiconductor device according to claim 3,
wherein the portion of the gate electrode comprises a titanium silicide film, a titanium nitride film, a silicide film of a first metal, and a first metal film in this order from the bottom surface of the metal laminating wiring,
on the bit line contact plug, the bit line comprises the titanium silicide film, the titanium nitride film, the silicide film of the first metal, and the first metal film in this order from the bottom surface of the metal laminating wiring, and
in a portion other than portion on the bit line contact plug, the bit line comprises a titanium film, the titanium nitride film, the silicide film of the first metal, and the first metal film in this order from the bottom surface of the metal laminating wiring.

5. The semiconductor device according to claim 4,
wherein the first metal is a refractory metal.

6. The semiconductor device according to claim 5,
wherein the first metal is at least one metal selected from the group consisting of tungsten, cobalt, nickel, and tantalum.

7. The semiconductor device according to claim 3,
wherein the memory cell region further comprises:
a buried gate electrode;
a gate insulating film formed between the buried gate electrode and the semiconductor substrate; and
first and second impurity diffusion layers formed in the semiconductor substrate in opposite sides of the buried gate electrode,
wherein the bit line contact plug is connected to the first impurity diffusion layer.

8. The semiconductor device according to claim 7,
wherein the first impurity diffusion layer is formed from the upper surface of the semiconductor substrate to a deeper position than the buried gate electrode.

9. The semiconductor device according to claim 1,
wherein the peripheral circuit region comprises:
an n-channel MOS transistor including the gate electrode; and
a p-channel MOS transistor including the gate electrode,
wherein the gate electrode of the n-channel MOS transistor comprises:
the metal laminating wiring; and
a polysilicon film containing an n-type impurity below the metal laminating wiring, and
wherein the gate electrode of the p-channel MOS transistor comprises:
the metal laminating wiring; and
a polysilicon film containing a p-type impurity below the metal laminating wiring.

10. A semiconductor device, comprising:
a memory cell region and a peripheral circuit region on a semiconductor substrate;
a metal laminating wiring extending over the memory cell region and the peripheral circuit region;
a buried gate electrode, and first and second impurity diffusion layers formed in the semiconductor substrate in opposite sides of the buried gate electrode, in the peripheral circuit region;
an n-channel MOS transistor including a gate electrode, and a p-channel MOS transistor including a gate electrode, in the memory cell region,
wherein the metal laminating wiring is a bit line connected to the first impurity diffusion layer through a bit line contact plug in the memory cell region,
the metal laminating wiring is a portion of a wiring for the peripheral circuit region connected to the bit line and portions of the gate electrodes of the n-channel MOS transistor and the p-channel MOS transistor connected to the wiring for the peripheral circuit region, in the peripheral circuit region, and
a height of a bottom surface of the metal laminating wiring disposed in the memory cell region, from an upper surface of the semiconductor substrate is substantially the same as the height of the bottom surface of the metal laminating wiring disposed in the peripheral circuit region, from the upper surface of the semiconductor substrate.

11. The semiconductor device according to claim 10,
wherein a difference between a first height and a second height is 5 nm or less,
wherein the first height is the height of the bottom surface of the metal laminating wiring disposed in the memory cell region, from the upper surface of the semiconductor substrate, and
wherein the second height is the height of the bottom surface of the metal laminating wiring disposed in the peripheral circuit region, from the upper surface of the semiconductor substrate.

12. The semiconductor device according to claim 10,
wherein the bit line contact plug includes a polysilicon film connected to the bit line and containing an impurity.

13. The semiconductor device according to claim 12,
wherein the portions of the gate electrodes of the n-channel MOS transistor and the p-channel MOS transistor comprise a titanium silicide film, a titanium nitride film, a silicide film of a first metal, and a first metal film in this order from the bottom surface of the metal laminating wiring,
on the bit line contact plug, the bit line comprises the titanium silicide film, the titanium nitride film, the silicide film of the first metal, and the first metal film in this order from the bottom surface of the metal laminating wiring, and
in a portion other than portion on the bit line contact plug, the bit line comprises a titanium film, the titanium nitride film, the silicide film of the first metal, and the first metal film in this order from the bottom surface of the metal laminating wiring.

14. The semiconductor device according to claim 13,
wherein the first metal is a refractory metal.

15. The semiconductor device according to claim 14,
wherein the first metal is at least one metal selected from the group consisting of tungsten, cobalt, nickel, and tantalum.

16. The semiconductor device according to claim 10,
wherein the first impurity diffusion layer is formed from the upper surface of the semiconductor substrate to a deeper position than the buried gate electrode.

17. The semiconductor device according to claim 10,
wherein the gate electrode of the n-channel MOS transistor further comprises a polysilicon film containing an n-type impurity below the metal laminating wiring, and
wherein the gate electrode of the p-channel MOS transistor further comprises a polysilicon film containing a p-type impurity below the metal laminating wiring.
